(19) United States
(12) Patent Application Publication
(10) Pub. No.: US 2025/0194071 A1
(43) Pub. Date: Jun. 12, 2025

(54) SEMICONDUCTOR DEVICE INCLUDING SOURCE/DRAIN PATTERNS AND SEPARATION PATTERN BETWEEN SOURCE/DRAIN PATTERNS

(71) Applicant: Samsung Electronics Co., Ltd., Suwon-si (KR)

(72) Inventors: Kyunghee CHO, Suwon-si (KR); Hyojin KIM, Suwon-si (KR); Donghoon HWANG, Suwon-si (KR); Byungho MOON, Suwon-si (KR)

(73) Assignee: Samsung Electronics Co., Ltd., Suwon-si (KR)

(21) Appl. No.: 18/745,040

(22) Filed: Jun. 17, 2024

(30) Foreign Application Priority Data
Dec. 8, 2023 (KR) 10-2023-0177902

(51) Int. Cl. H10B 10/00

(52) U.S. Cl. CPC H10B 10/125

(57) ABSTRACT

A semiconductor device may include a first lower separation pattern including a first portion, the first portion including a first lower separation region and a first upper separation region on the first lower separation region; a first source/drain pattern and a second source/drain pattern on both sides of the first upper separation region; a common source/drain contact plug on the first and second source/drain patterns and the first upper separation region, and electrically connected to the first and second source/drain patterns; a first conductive via electrically connected to the common source/drain contact plug and on the common source/drain contact plug; and a first wiring pattern electrically connected to the first conductive via and on the first conductive via.

### CROSS-REFERENCE TO RELATED APPLICATION(S)

This application claims benefit of priority to Korean Patent Application No. 10-2023-0177902, filed on Dec. 8, 2023 in the Korean Intellectual Property Office, the disclosure of which is incorporated herein by reference in its entirety.

### BACKGROUND

Example embodiments relate to a semiconductor device including source/drain patterns and a separation pattern between the source/drain patterns, and/or a method of manufacturing the same.

As demand for high performance, high speed, and/or multifunctionality of a semiconductor device has increased, integration density of a semiconductor device has increased. In manufacturing a semiconductor device having a fine pattern in response to the trend for high integration density of a semiconductor device, it may be necessary to implement patterns having a fine width or a fine spacing distance. Also, to overcome limitations in operating properties due to reduction of a size of metal oxide semiconductor FET (planar MOSFET), efforts for developing a semiconductor device including a transistor including channels in a three-dimensional structure have been made.

### SUMMARY

An example embodiment provides a semiconductor device having improved integration density.

According to an example embodiment, a semiconductor device may include a first lower separation pattern including a first portion, the first portion including a first lower separation region and a first upper separation region on the first lower separation region; a first source/drain pattern and a second source/drain pattern on both sides of the first upper separation region, respectively; a common source/drain contact plug on the first source/drain pattern, the second source/drain pattern, and the first upper separation region, the common source/drain contact plug being electrically connected to the first source/drain pattern and the second source/drain pattern; a first conductive via electrically connected to the common source/drain contact plug and on the common source/drain contact plug; and a first wiring pattern electrically connected to the first conductive via and on the first conductive via.

According to an example embodiment, a semiconductor device may include a lower separation pattern including overlap regions and a non-overlap region between the overlap regions, a first side surface of the lower separation pattern opposing a second side surface of the lower separation pattern; upper separation patterns on the overlap regions of the lower separation pattern, the upper separation patterns being spaced apart from each other; a first channel region, a first gate, and a first source/drain pattern on the first side surface of the lower separation pattern; a second channel region, a second gate, and a second source/drain pattern on the second side surface of the lower separation pattern; a source/drain contact plug on the first source/drain pattern, the second source/drain pattern, and the non-overlap region of the lower separation pattern, the source/drain contact plug being electrically connected to the first source/drain pattern and second source/drain pattern; a first conductive via on the source/drain contact plug; and a first wiring pattern on the first conductive via. A portion of the source/drain contact plug vertically overlapping the non-overlap region may be between the upper separation patterns.

According to an example embodiment, a semiconductor device may include a first lower separation pattern and a second lower separation pattern, the second lower separation pattern being parallel to the first lower separation pattern; a first access source/drain pattern, a first access channel region, a first common source/drain pattern, a first NMOS channel region, and a first NMOS source/drain pattern on a side surface of the first lower separation pattern facing the second lower separation pattern, and arranged sequentially in a first horizontal direction; a first PMOS source/drain pattern, a first PMOS channel region, and a second PMOS source/drain pattern on a first side surface of the second lower separation pattern facing the first lower separation pattern, and arranged sequentially in the first horizontal direction; a fourth PMOS source/drain pattern, a second PMOS channel region, and a third PMOS source/drain pattern disposed on a second side surface of the second lower separation pattern opposing a first side surface of the second lower separation pattern, and arranged sequentially in the first horizontal direction; a first access gate vertically overlapping the first access channel region; a first NMOS gate vertically overlapping the first NMOS channel region; a first PMOS gate vertically overlapping the first PMOS channel region and connected to the first NMOS gate; a second PMOS gate vertically overlapping the second PMOS channel region; a first source/drain contact plug on the first NMOS source/drain pattern; a second source/drain contact plug electrically connected to the first common source/drain pattern and the first PMOS source/drain pattern; a third source/drain contact plug on the first access source/drain pattern; a fourth source/drain contact plug on the second PMOS source/drain pattern; a first gate connection plug connected to the first access gate; and a second gate connection plug including a first extension portion and a second extension portion. The first extension portion may extend in the first horizontal direction and may be connected to the second source/drain contact plug. A second horizontal direction may be perpendicular to the first horizontal direction. The second extension portion may extend from the first extension portion in the second horizontal direction, vertically overlap the second lower separation pattern, and may be connected to the second PMOS gate. The first common source/drain pattern, the first PMOS source/drain pattern, and the third PMOS source/drain pattern may be arranged sequentially in the second horizontal direction, and The second extension portion of the second gate connection plug may be in contact with a gate electrode of the second PMOS gate.

### BRIEF DESCRIPTION OF DRAWINGS

The above and other aspects, features, and advantages in the example embodiment will be more clearly understood from the following detailed description, taken in combination with the accompanying drawings, in which:

FIGS. 1 to 7 are diagrams illustrating a semiconductor device according to an example embodiment of the present disclosure;

FIG. 8 is a cross-sectional diagram illustrating a modified example of a semiconductor device according to an example embodiment of the present disclosure;

FIG. 9 is a cross-sectional diagram illustrating a modified example of a semiconductor device according to an example embodiment of the present disclosure;

FIG. 10 is a cross-sectional diagram illustrating a modified example of a semiconductor device according to an example embodiment of the present disclosure;

FIG. 11 is a cross-sectional diagram illustrating a modified example of a semiconductor device according to an example embodiment of the present disclosure; and

FIGS. 12A to 23C are cross-sectional diagrams illustrating a method of manufacturing a semiconductor device according to an example embodiment of the present disclosure.

### DETAILED DESCRIPTION

Hereinafter, terms such as “upper,” “middle,” and “lower” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

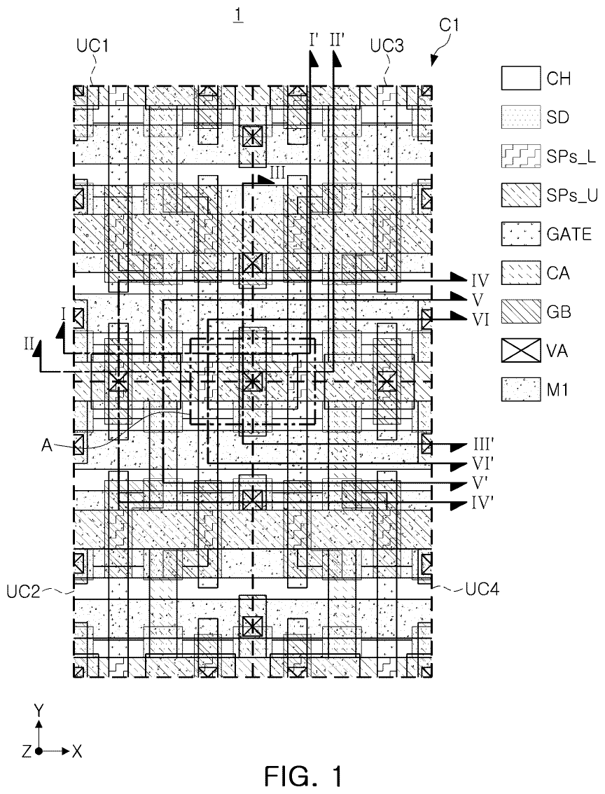

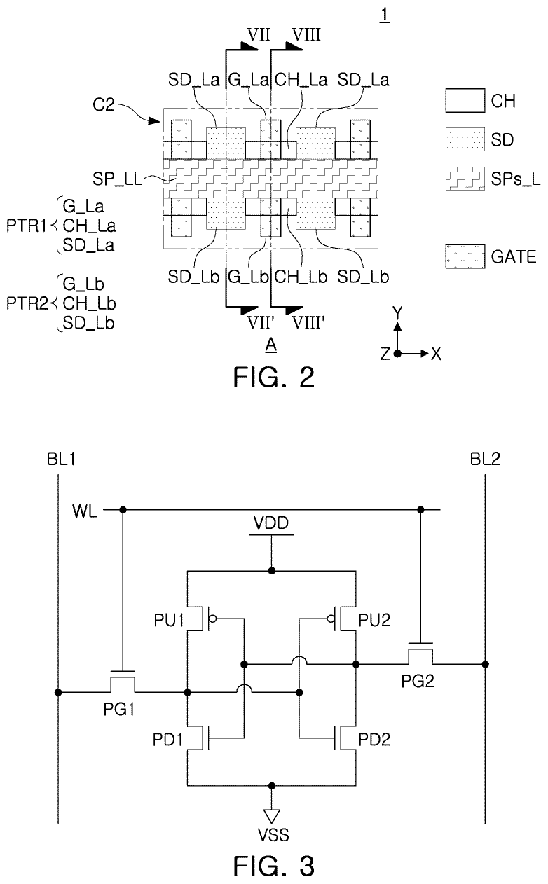

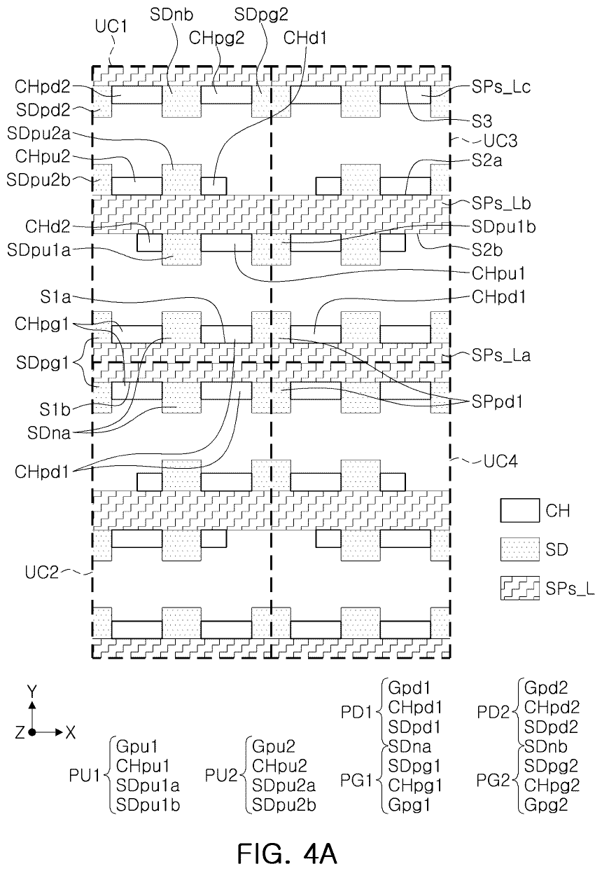

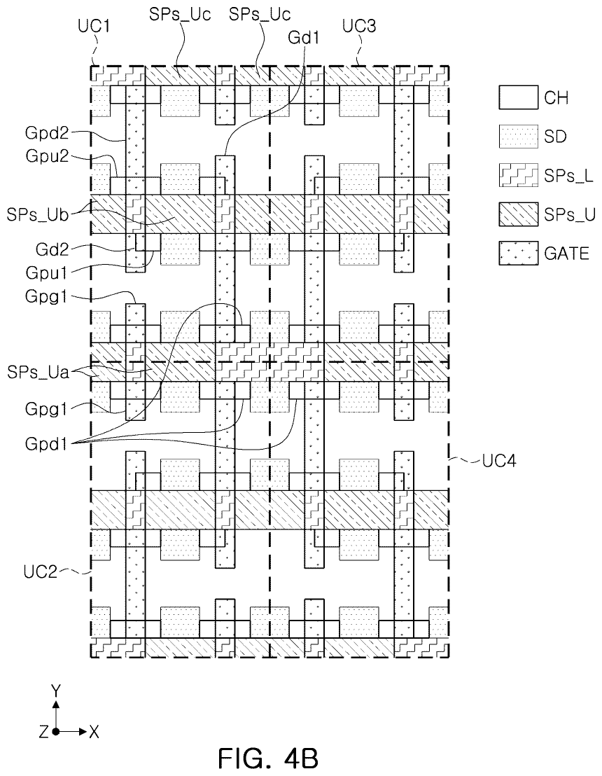

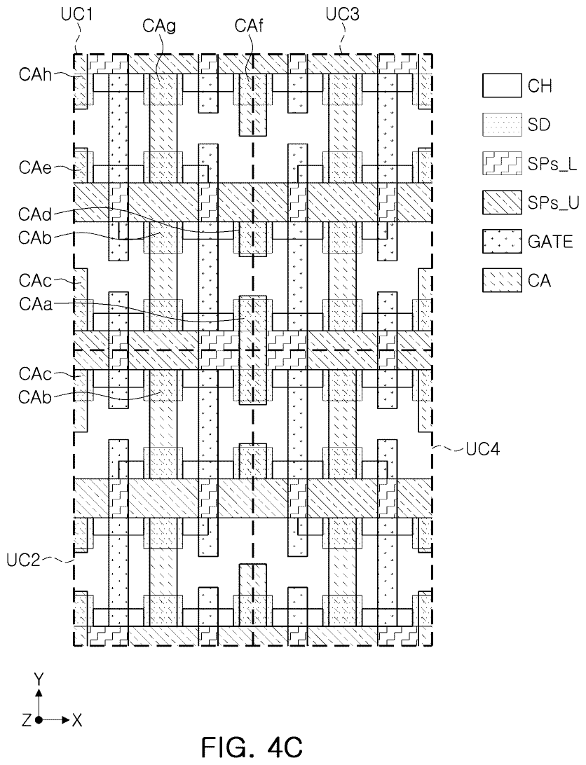

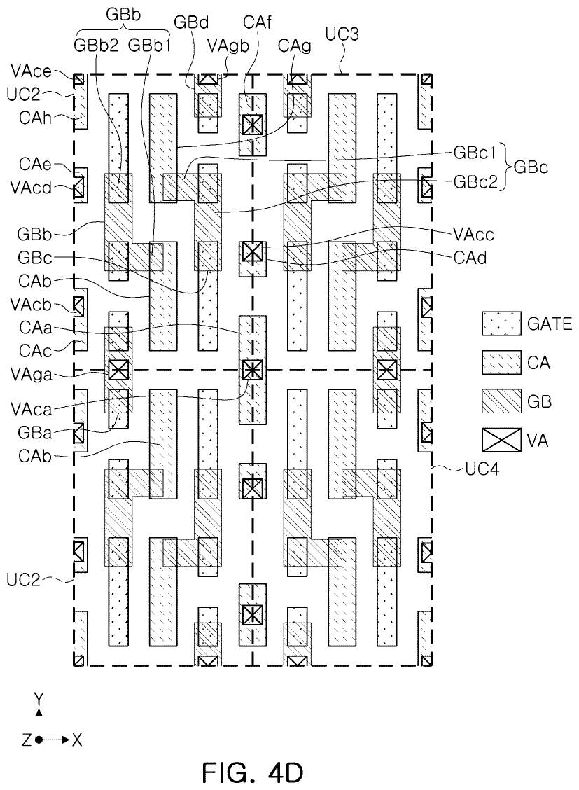

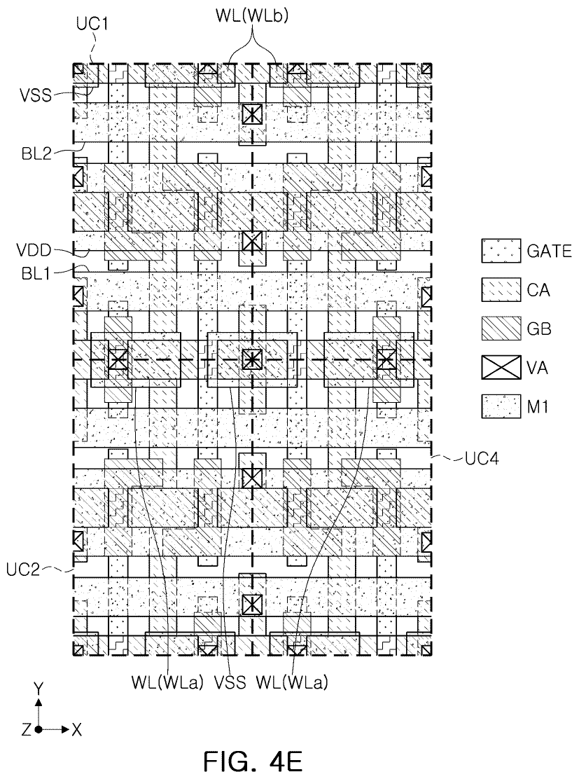

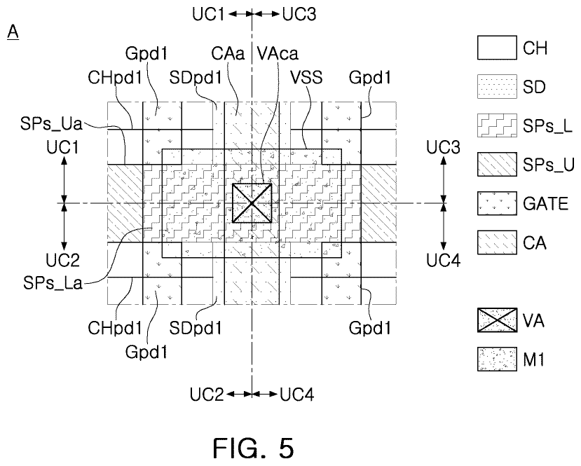

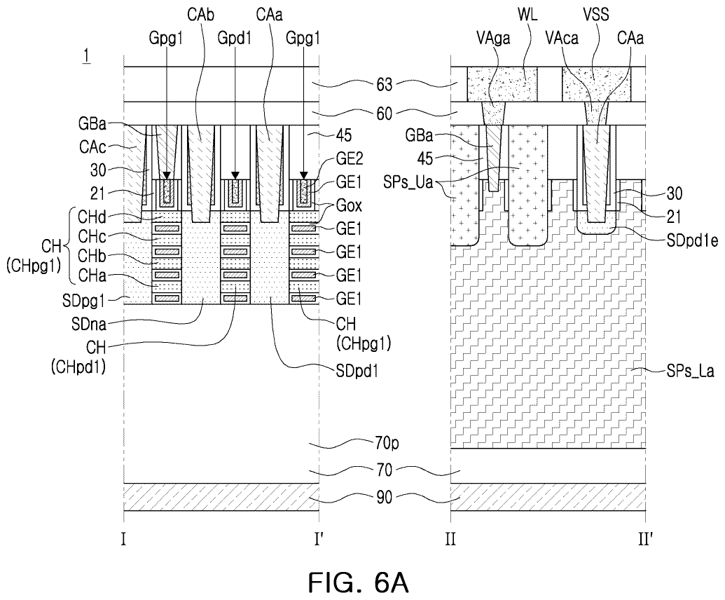

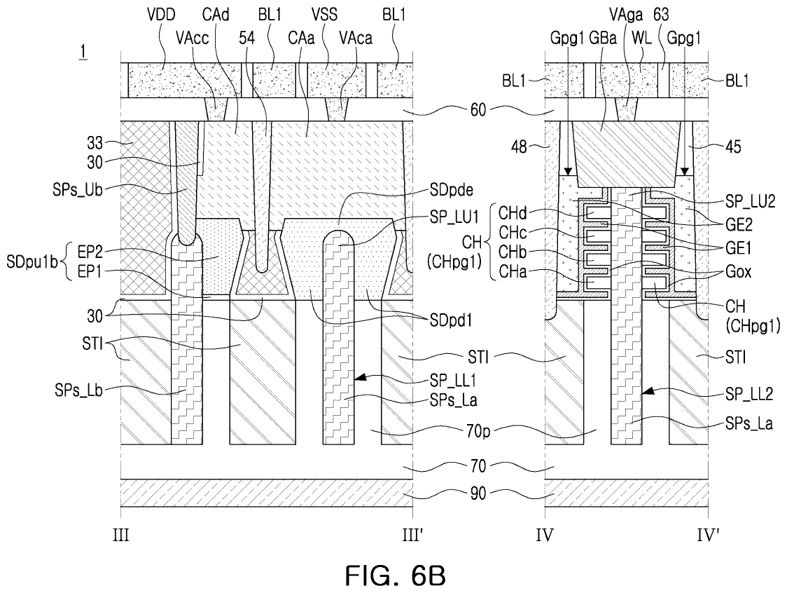

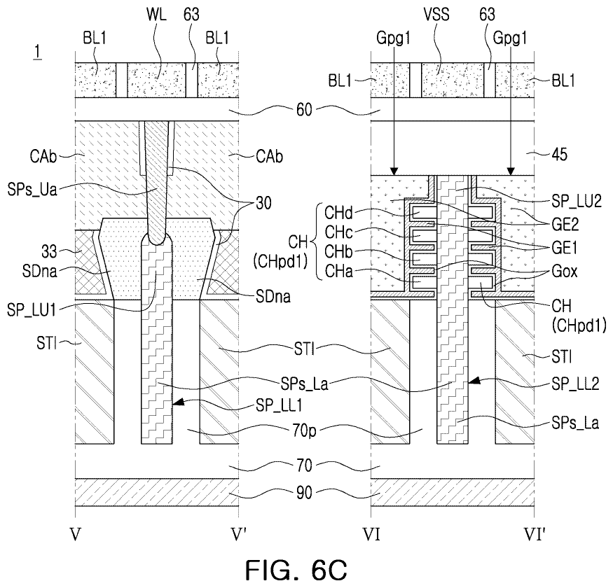

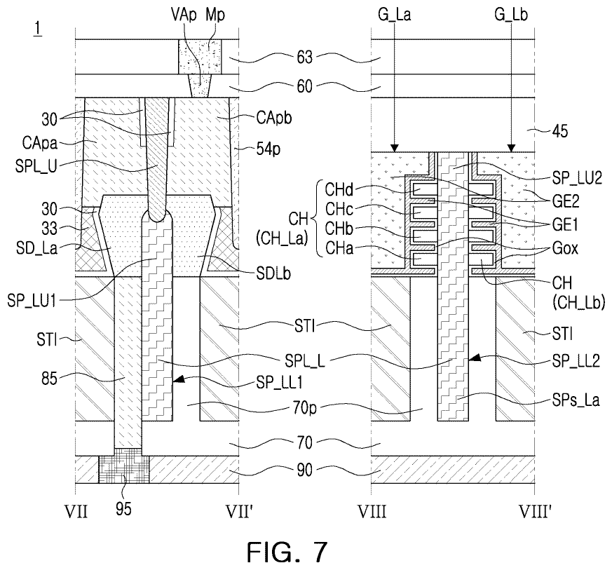

With reference to FIGS. 1 to 7, examples of a semiconductor device according to example embodiments will be described. As for FIGS. 1 to 7, FIG. 1 is a top view illustrating an example of a first circuit region of a semiconductor device according to example embodiments. FIG. 2 is a top view illustrating an example of a second circuit region of a semiconductor device according to example embodiments. FIG. 3 is a circuit diagram illustrating a first circuit region in FIG. 1. FIGS. 4A to 4E are top views illustrating a portion of elements of the first circuit region in FIG. 1. FIG. 5 is an enlarged diagram illustrating region “A” in FIG. 1. FIG. 6A is a cross-sectional diagram illustrating a region taken along lines I-I′ and II-II′ in FIG. 1. FIG. 6B is a cross-sectional diagram illustrating a region taken along lines III-III′ and IV-IV′ in FIG. 1. FIG. 6C is a cross-sectional diagram illustrating a region taken along lines V-V′ and VI-VI′ in FIG. 1. FIG. 7 is a cross-sectional diagram illustrating a region taken along lines VII-VII′ and VIII-VIII′ in FIG. 2.

First, referring to FIGS. 1, 2, and 3, the semiconductor device 1 according to an example embodiment may include a first circuit region C1 and a second circuit region C2. The first circuit region C1 may be a memory cell array region of SRAM including a plurality of memory unit cell regions, and the second circuit region C2 may be a logic circuit region including peripheral transistors PTR1 and PTR2.

Referring to FIGS. 1, 2, 3, 4A, 4B and 5, the first circuit region C1 in FIG. 1 is a top view illustrating four memory unit cell regions UC1, UC2, UC3, and UC4 in FIG. 1. FIG. 3 is a circuit diagram illustrating a memory unit cell region among the memory unit cell regions UC1, UC2, UC3, and UC4. FIG. 4A is a top view illustrating lower separation patterns SPs_L, channel regions CH, and source/drain patterns SD in the first circuit region C1 in FIG. 1. FIG. 4B is a top view additionally illustrating gates GATE and upper separation patterns SPs_L in the top view in FIG. 4A.

The memory unit cell regions UC1, UC2, UC3, and UC4 may include a first memory unit cell region UC1, a second memory unit cell region UC2, a third memory unit cell region UC3, and a fourth memory unit cell region UC4.

The first memory unit cell region UC1 and the third memory unit cell region UC3 may be adjacent to each other in the first horizontal direction X and may be mirror-symmetrical. The second memory unit cell region UC2 and the fourth memory unit cell region UC4 may be adjacent to each other in the first horizontal direction X and may be mirror-symmetrical. The first memory unit cell region UC1 and the second memory unit cell region UC2 may be adjacent to each other in the second horizontal direction Y and may be mirror-symmetrical. The third memory unit cell region UC3 and the fourth memory unit cell region UC4 may be adjacent to each other in the second horizontal direction Y and may be mirror-symmetrical. The second horizontal direction Y may be perpendicular to the first horizontal direction X.

The first and second circuit regions C1 and C2 may include lower separation patterns SPs_L and upper separation patterns SPs_U on the lower separation patterns SPs_L.

The lower separation patterns SPs_L may include a first lower separation pattern SPs_La, a second lower separation pattern SPs_Lb, and a third lower separation pattern SPs_Lc disposed in the first circuit region C1 and a peripheral lower separation pattern SPL_L disposed in the second circuit region C2.

The upper separation patterns SPs_U may include first, second and third upper separation patterns SPs_Ua, SPs_Ub, and SPs_Uc disposed in the first circuit region C1 and peripheral upper separation patterns (SPL_U in FIG. 6) disposed in the second circuit region C2.

In each of the lower separation patterns SPs_L, regions vertically overlapping the upper separation patterns SPs_U may be defined as “overlap regions,” and regions not vertically overlapping the upper separation patterns SPs_U may be defined as “non-overlap regions.” Accordingly, the upper separation patterns SPs_U may be disposed on overlap regions of the lower separation patterns SPs_L.

Each of the lower separation patterns SPs_L may extend to the first horizontal direction X. The lower separation patterns SPs_L may be a line shape spaced apart from each other in the second horizontal direction Y.

Each of the memory unit cell regions UC1, UC2, UC3, and UC4 may overlap the three lower separation patterns SPs_L adjacent to each other in the second horizontal direction Y among the lower separation patterns SPs_L. For example, the lower separation patterns SPs_L of the first circuit region C1 may include a first lower separation pattern SPs_La, a second lower separation pattern SPs_Lb and a third lower separation pattern SPs_Lc, overlapping the first memory unit cell region UC1 and arranged sequentially in the second horizontal direction Y. The second lower separation pattern SPs_Lb may be disposed between the first lower separation pattern SPs_La and the third lower separation pattern SPs_Lc.

In the first circuit region C1, the lower separation patterns SPs_L passing through a central portion of each of the memory unit cell regions UC1, UC2, UC3, and UC4 may be referred to as the second lower separation pattern SPs_Lb. For example, the second lower separation pattern SPs_Lb may cross central portions of the first and third memory unit cell regions UC1 and UC3.

The first lower separation pattern SPs_La may cross between the first memory unit cell region UC1 and the second memory unit cell region UC2, and between the third memory unit cell region UC3 and the fourth memory unit cell region UC4.

Each of the first to fourth memory unit cell regions UC1, UC2, UC3, and UC4 may include first and second pull-up transistors PU1 and PU2, first and second pull-down transistors PD1 and PD2, and first and second access transistors PG1 and PG2.

The first circuit region C1 may further include a wordline WL, a first bitline BL1, a second bitline BL2, a ground voltage line VSS, and a voltage power line VDD electrically connected to the first to fourth memory unit cell regions UC1, UC2, UC3, and UC4.

The first and second pull-down transistors PD1 and PD2 and the first and second access transistors PG1 and PG2 may be NMOS transistors, and the first and second pull-up transistors PU1 and PU2 may be PMOS transistors.

The first pull-up transistor PU1 may be referred to as a first PMOS transistor, and the second pull-up transistor PU2 may be referred to as a second PMOS transistor. The first pull-down transistor PD1 may be referred to as a first NMOS transistor, and the second pull-down transistor PD2 may be referred to as a second NMOS transistor.

The first pull-up transistor PU1 may include a first PMOS channel region CHpu1, a first PMOS source/drain pattern SDpu1a, a second PMOS source/drain pattern SDpu1b, and a first PMOS gate Gpu1. The second pull-up transistor PU2 may include a second PMOS channel region CHpu2, a third PMOS source/drain pattern SDpu2a, a fourth PMOS source/drain pattern SDpu2b, and a second PMOS gate Gpu2.

The first pull-down transistor PD1 may include a first NMOS channel region CHpd1, a first NMOS source/drain pattern SDpd1, a first common source/drain pattern SDna, and a first NMOS gate Gpd1. The second pull-down transistor PD2 may include a second NMOS channel region CHpd2, a second NMOS source/drain pattern SDpd2, a second common source/drain pattern SDnb, and a second NMOS gate Gpd1.

The first access transistor PG1 may include a first access channel region CHpg1, a first access source/drain pattern SDpg1, a first common source/drain pattern SDna, and a first access gate Gpg1. The second access transistor PG2 may include a second access channel region CHpg2, a second access source/drain pattern SDpg2, a second common source/drain pattern SDnb, and a second access gate Gpg2.

The first pull-down transistor PD1 and the first access transistor PG1 may share the first common source/drain pattern SDna. The second pull-down transistor PD2 and the second access transistor PG2 may share the second common source/drain pattern SDnb.

In the second circuit region C2, the peripheral transistors PTR1 and PTR2 may include a first peripheral transistor PTR1 and a second peripheral transistor PTR2 facing each other with the peripheral lower separation pattern SPL_L interposed therebetween.

The first peripheral transistor PTR1 may include a first peripheral channel region CH_La, a first peripheral gate G_La overlapping the first peripheral channel region CH_La, and first peripheral source/drain patterns SD_La on both sides of the first peripheral channel region CH_La.

The second peripheral transistor PTR2 may include a second peripheral channel region CH_Lb, a second peripheral gate G_Lb overlapping the second peripheral channel region CH_Lb, and second peripheral source/drain patterns SD_Lb on both sides of the second peripheral channel region CH_Lb.

The channel regions CH may include the first PMOS channel region CHpu1, the second PMOS channel region CHpu2, the first NMOS channel region CHpd1, the second NMOS channel region CHpd2, the first access channel region CHpg1, and the second access channel region CHpg2, disposed in the first circuit region C1, and the first and second peripheral channel regions CH_La and CH_Lb disposed in the second circuit region C2.

The source/drain patterns SD may include the first PMOS source/drain pattern SDpu1a, the second PMOS source/drain pattern SDpu1b, the third PMOS source/drain pattern SDpu2a, the fourth PMOS source/drain pattern SDpu2b, the first NMOS source/drain pattern SDpd1, the first common source/drain pattern SDna, the second NMOS source/drain pattern SDpd2, and the second common source/drain pattern SDnb, disposed in the first circuit region C1, and the first and second peripheral source/drain patterns SD_La and SD_Lb disposed in the second circuit region C2. Among the source/drain patterns SD, the first PMOS source/drain pattern SDpu1a, the second PMOS source/drain pattern SDpu1b, the third PMOS source/drain pattern SDpu2a and the fourth PMOS source/drain pattern SDpu2b may include an epitaxial material layer having P-type conductivity.

Among the source/drain patterns SD, the first NMOS source/drain pattern SDpd1, the first common source/drain pattern SDna, the second NMOS source/drain pattern SDpd2, the second common source/drain pattern SDnb, the first access source/drain pattern SDpg1, and the second access source/drain pattern SDpg2 may include an epitaxial material layer having N-type conductivity.

The gates GATE may include the first PMOS gate Gpu1, the second PMOS gate Gpu2, the first NMOS gate Gpd1, the second NMOS gate Gpd2, the first access gate Gpg1, and the second access gate Gpg2, disposed in the first circuit region C1, and the first and second peripheral gates G_La and G_Lb disposed in the second circuit region C2.

The first pull-down transistor PD1 and the first access transistor PG1 may be connected to each other in series.

The first NMOS source/drain pattern SDpd1 of the first pull-down transistor PD1 may be a source, and the first NMOS source/drain pattern SDpd1 may be electrically connected to the ground voltage line VSS.

The first access source/drain pattern SDpg1 of the first access transistor PG1 may be a drain, and the first access source/drain pattern SDpg1 may be electrically connected to the first bitline BL1.

The second pull-down transistor PD2 and the second access transistor PG2 may be connected to each other in series. The second NMOS source/drain pattern SDpd2 of the second pull-down transistor PD2 may be a source, and the second NMOS source/drain pattern SDpd2 may be electrically connected to the ground voltage line VSS.

The second access source/drain pattern SDpg2 of the second access transistor PG2 may be a drain, and the second access source/drain pattern SDpg2 may be electrically connected to the second bitline BL2.

The first common source/drain pattern SDna, which may be a drain of the first pull-down transistor PD1 and a source of the first access transistor PG1, and the first PMOS source drain pattern SDpu1a, which may be a drain of the first pull-up transistor PU1, may be first nodes N1 electrically connected to each other. A gate electrode of the second NMOS gate Gpd2 of the second pull-down transistor PD2 and a gate electrode of the second PMOS gate Gpu2 of the second pull-up transistor PU2 may be electrically connected to the first node N1. Accordingly, the first common source/drain pattern SDna, the first PMOS source drain pattern SDpu1a, the gate electrode of the second NMOS gate Gpd2, and the gate electrode of the second PMOS gate Gpu2 may be electrically connected to each other.

The second common source/drain pattern SDnb, which may be a drain of the second pull-down transistor PD2 and a source of the second access transistor PG2, and the third PMOS source/drain pattern SDpu2a, which may be a drain of the second pull-up transistor PU2, may be second nodes N2 electrically connected to each other. A gate electrode of the first NMOS gate Gpd1 of the first pull-down transistor PD1 and a gate electrode of the first PMOS gate Gpu1 of the first pull-up transistor PU1 may be electrically connected to the second node N2. Accordingly, the second common source/drain pattern SDnb, the third PMOS source/drain pattern SDpu2a, the gate electrode of the first NMOS gate Gpd1, and the gate electrode of the first PMOS gate Gpu1 may be electrically connected to each other.

The ground voltage line VSS may be electrically connected to the first NMOS source/drain pattern SDpd1 and the second NMOS source/drain pattern SDpd2.

The power voltage line VDD may be electrically connected to the second PMOS source/drain pattern SDpu1b and the fourth PMOS source/drain pattern SDpu2b.

The wordline WL may be electrically connected to a gate electrode of the first access gate Gpg1 of the first access transistor PG1 and a gate electrode of the second access gate Gpg2 of the second access transistor PG2.

The channel regions CH may further include a first dummy channel region CHd1 and a second dummy channel region CHd2.

Hereinafter, the elements disposed in the first memory unit cell region UC1 among the first to fourth memory unit cell regions UC1, UC2, UC3, and UC4 will be mainly described. Hereinafter, even though there is no description of the elements disposed in the second to fourth memory unit cell regions UC1, UC2, UC3, and UC4, the first to fourth memory unit cell regions UC1, UC2, UC3, and UC4 may be mirror-symmetrical structures as described above, such that as for the elements disposed in the second to fourth memory unit cell regions UC1, UC2, UC3, and UC4, the elements disposed in the first memory unit cell region UC1 may be understood as mirror-symmetrical elements as described above.

The first lower separation pattern SPs_La may have a first side surface Sla facing the second lower separation pattern SPs_Lb and a second side surface S1b opposing the first side surface S1a. The second lower separation pattern SPs_Lb may have a first side surface S2a facing the third lower separation pattern SPs_Lc and a second side surface S2b opposing the first side surface S2a. The third lower separation pattern SPs_Lc may have a side surface S3 facing the second lower separation pattern SPs_Lb.

The first access source/drain pattern SDpg1, the first access channel region CHpg1, the first common source/drain pattern SDna, and first NMOS channel region CHpd1, and the first NMOS source/drain pattern SDpd1 may be arranged in order from the first memory unit cell region UC1 in the first horizontal direction X toward the third memory unit cell region UC3. The first access source/drain pattern SDpg1, the first access channel region CHpg1, the first common source/drain pattern SDna, and first NMOS channel region CHpd1, and the first NMOS source/drain pattern SDpd1 may be in contact with the first side surface S1a of the first lower separation pattern SPs_La on the first side surface S1a of the first lower separation pattern SPs_La.

The second dummy channel region CH2d, the first PMOS source/drain pattern SDpu1a, the first PMOS channel region CHpu1a, and the second PMOS source/drain pattern SDpu1b may be arranged in order from the first memory unit cell region UC1 in the first horizontal direction X toward the third memory unit cell region UC3. The second dummy channel region CH2d, the first PMOS source/drain pattern SDpu1a, the first PMOS channel region CHpu1, and the second PMOS source/drain pattern SDpu1b may be in contact with the second side surface S2b of the second lower separation pattern SPs_Lb on the second side surface S2b of the second lower separation pattern SPs_Lb.

The fourth PMOS source/drain pattern SDpu2b, the second PMOS channel region CHpu2, the third PMOS source/drain pattern SDpu2a, and the first dummy channel region CHd1 may be arranged in order from the first memory unit cell region UC1 in the first horizontal direction X toward the third memory unit cell region UC3. The fourth PMOS source/drain pattern SDpu2b, the second PMOS channel region CHpu2, the third PMOS source/drain pattern SDpu2a, and the first dummy channel region CHd1 may be in contact with the first side surface S2a of the second lower separation pattern SPs_Lb on the first side surface S2a of the second lower separation pattern SPs_Lb.

The second NMOS source/drain pattern SDpd2, the second NMOS channel region CHpd2, the second common source/drain pattern SDnb, the second access channel region CHpg2, and the second access source/drain pattern SDpg2 may be arranged in order from the first memory unit cell region UC1 in the first horizontal direction X toward the third memory unit cell region UC3. The second NMOS source/drain pattern SDpd2, the second NMOS channel region CHpd2, the second common source/drain pattern SDnb, the second access channel region CHpg2, and the second access source/drain pattern SDpg2 may be in contact with the side surface S3 of the third lower separation pattern SPs_Lc on the side surface S3 of the third lower separation pattern SPs_Lc.

The first access source/drain pattern SDpg1, the fourth PMOS source/drain pattern SDpu2b, and the second NMOS source/drain pattern SDpd2 may be arranged in order from the second memory unit cell region UC2 in the second vertical direction Y toward the first memory unit cell region UC1.

The first access channel region CHpg1, the second dummy channel region CHd2, the second PMOS channel region CHpu2, and the second NMOS channel region CHpd2 may be arranged sequentially in the second vertical direction Y.

The first common source/drain pattern SDna, the first PMOS source/drain pattern SDpu1a, the third PMOS source/drain pattern SDpu2a, and the second common source/drain pattern SDnb may be arranged sequentially in the second vertical direction Y.

The first NMOS channel region CHpd1, the first PMOS channel region CHpu1, the first dummy channel region CH1d, and the second access channel region CHpg2 may be arranged sequentially in the second vertical direction Y.

The first access channel region CHpg1, the second PMOS channel region CHpu2, the second NMOS channel region CHpd2, the first NMOS channel region CHpd1, the first PMOS channel region CHpu1, and the second access channel region CHpg2 may have substantially the same width in the first horizontal direction X.

Each of the first and second dummy channel regions CHd1 and CHd2 may have a width smaller than a width of each of the first access channel region CHpg1, the second PMOS channel region CHpu2, the second NMOS channel region CHpd2, the first NMOS channel region CHpd1, the first PMOS channel region CHpu1, and the second access channel region CHpg2 in the first horizontal direction X.

A width of each of the source/drain patterns SD may be greater than a width of each of the channel regions CH in the second horizontal direction Y.

The gates GATE may further include a first dummy gate Gd1 and a second dummy gate Gd2.

The first access gate Gpg1, the second dummy gate Gd2, the second PMOS gate Gpu2, and the second NMOS gate Gpd2 may be arranged sequentially in the second horizontal direction Y.

The first access gate Gpg1 may be in contact with the side surface of the first lower separation pattern SPs_La facing the second lower separation pattern SPs_Lb, may vertically overlap the first access channel region CHpg1 and may extend in the second horizontal direction Y.

The second dummy gate Gd2 may be in contact with the second side surface S2b of the second lower separation pattern SPs_Lb facing the first lower separation pattern SPs_La, may vertically overlap the second dummy channel region CHd2, may extend in a direction toward the first lower separation pattern SPs_La, and may be spaced apart from the first access gate Gpg1.

The second PMOS gate Gpu2 and the second NMOS gate Gpd2 may be disposed between the second lower separation pattern SPs_Lb and the third lower separation pattern SPs_Lc and may be connected to each other.

The second PMOS gate Gpu2 may be in contact with the first side surface S2a of the second lower separation pattern SPs_Lb facing the third lower separation pattern SPs_Lc, may vertically overlap the second PMOS channel region CHpu2 and may extend in a direction toward the third lower separation pattern SPs_Lc.

The second NMOS gate Gpd2 may be in contact with the side surface S3 of the third lower separation pattern SPs_Lc facing the second lower separation pattern SPs_Lb, may vertically overlap the second NMOS channel region CHpd2, may extend in a direction toward the second lower separation pattern SPs_Lb and may be connected to the second PMOS gate Gpu2.

The second PMOS gate Gpu2 and the second NMOS gate Gpd2 may have a bar shape extending in the second horizontal direction Y.

The first NMOS gate Gpd1 and the first PMOS gate Gpu1 may be disposed between the first lower separation pattern SPs_La and the second lower separation pattern SPs_Lb and may be connected to each other.

The first NMOS gate Gpd1 may be in contact with the first side surface S1a of the first lower separation pattern SPs_La facing the second lower separation pattern SPs_Lb, may vertically overlap the first NMOS channel region CHpd1, and may extend in a direction toward the second lower separation pattern SPs_Lb.

The first PMOS gate Gpu1 may be in contact with the second side surface S2b of the second lower separation pattern SPs_Lb facing the first lower separation pattern SPs_La, may vertically overlap the first PMOS channel region CHpu1, may extend in a direction toward the first lower separation pattern SPs_La and may be connected to the first NMOS gate Gpd1.

The first NMOS gate Gpd1 and the first PMOS gate Gpu1 may have a bar shape extending in the second horizontal direction Y.

The second access gate Gpg2 may be in contact with the side surface S3 of the third lower separation pattern SPs_Lc facing the second lower separation pattern SPs_Lb, may vertically overlap the second access channel region CHpg2, and may extend in a direction toward the second lower separation pattern SPs_Lb.

The first dummy gate Gd1 may be in contact with the first side surface S2a of the second lower separation pattern SPs_Lb facing the third lower separation pattern SPs_Lc, may vertically overlap the first dummy channel region CHd1, may extend in the direction toward the third lower separation pattern SPs_Lc and may be spaced apart from the second access gate Gpg2.

The upper separation patterns SPs_U may include first upper separation patterns SPs_Ua, second upper separation patterns SPs_Ub, and third upper separation patterns SPs_Uc.

The first upper separation patterns SPs_Ua may be disposed on the first lower separation pattern SPs_La and may be spaced apart from each other in the first horizontal direction X.

The first upper separation patterns SPs_Ua may be disposed on the first lower separation pattern SPs_La adjacent to the first access source/drain pattern SDpg1 and the first common source/drain pattern SDna, and may not be disposed on the first lower separation pattern SPs_La adjacent to the first access gate Gpg1, the first NMOS gate Gpd1 and the first NMOS source/drain pattern SDpd1.

The second upper separation patterns SPs_Ub may be disposed on the second lower separation pattern SPs_Lb and may be spaced apart from each other in the first horizontal direction X.

The second upper separation patterns SPs_Ub may be disposed on the second lower separation pattern SPs_Lb adjacent to the first to fourth PMOS source/drain patterns SDpu1a, SDpu1b, SDpu2a, SDpu2b, and may not be disposed on the second lower separation pattern SPs_Lb adjacent to the first and second PMOS gates Gpu1, Gpu2, and the first and second dummy gates Gd1, Gd2.

The third upper separation patterns SPs_Uc may be disposed on the third lower separation pattern SPs_Lc and may be spaced apart from each other in the first horizontal direction X.

The third upper separation patterns SPs_Uc may be disposed on the third lower separation pattern SPs_Lc adjacent to the second access source/drain pattern SDpg2 and the second common source/drain pattern SDnb, and may not be disposed on the third lower separation pattern SPs_Lc adjacent to the second access gate Gpg2, the second NMOS gate Gpd2 and the second NMOS source/drain pattern SDpd2.

The first memory unit cell region UC1 and the third memory unit cell region UC3 may share the first NMOS source/drain pattern SDpd1, the second PMOS source/drain pattern SDpu1b, and the second access source/drain pattern SDpg2. For example, half of the first NMOS source/drain pattern SDpd1, half of the second PMOS source/drain pattern SDpu1b, and half of the second access source/drain pattern SDpg2 may be disposed in the first memory unit cell region UC1, and the other half of the first NMOS source/drain pattern SDpd1, the other half of the second PMOS source/drain pattern SDpu1b, and the other half of the second access source/drain pattern SDpg2 may be disposed in the third memory unit cell region UC3.

The first lower separation pattern SPs_La may pass between the first memory unit cell region UC1 and the second memory unit cell region UC2, and may extend to a region between the third memory unit cell region UC3 and the fourth memory unit cell region UC4. A central axis of the first lower separation pattern SPs_La extending in the first horizontal direction X may be a boundary between the first memory unit cell region UC1 and the second memory unit cell region UC2.

The first NMOS source/drain pattern SDpd1 of the first and third memory unit cell regions UC1 and UC3 and the first NMOS source/drain pattern SDpd1 of the second and fourth memory unit cell regions UC2 and UC3 may face each other with the first lower separation pattern SPs_La interposed therebetween.

Referring to FIG. 4C along with FIGS. 1, 3, 4A, 4B and 5, the first circuit region C1 may further include source/drain contact plugs CA.

The source/drain contact plugs CA may include a first source/drain contact plug CAa, a second source/drain contact plug CAb, a third source/drain contact plug CAc, a fourth source/drain contact plug CAd, a fifth source/drain contact plug CAe, a sixth source/drain contact plug CAf, a seventh source/drain contact plug CAg, and an eighth source/drain contact plug CAh.

The first source/drain contact plug CAa may vertically overlap the first lower separation pattern SPs_La, the first and third memory unit cell regions UC1, the first NMOS source/drain pattern SDpd1 shared by UC3, and the first NMOS source/drain pattern SDpd1 shared by the second and fourth memory unit cell regions UC2 and UC3.

The first source/drain contact plug CAa may be electrically connected to the first NMOS source/drain pattern SDpd1 of the first and third memory unit cell regions UC1, UC3 and the first NMOS source/drain pattern SDpd1 of the second and fourth memory unit cell regions UC2 and UC3. The first source/drain contact plug CAa may have a bar shape extending in the second horizontal direction Y. The first source/drain contact plug CAa may also be referred to as a common source/drain contact plug.

Within the first memory unit cell region UC1, the second source/drain contact plug CAb may vertically overlap the first common source/drain pattern SDna, may extend in the second horizontal direction Y and may vertically overlap the first PMOS source/drain pattern SDpu1a. The second source/drain contact plug CAb may be electrically connected to the first common source/drain pattern SDna and the first PMOS source/drain pattern SDpu1a.

Within the first memory unit cell region UC1, the third source/drain contact plug CAc may vertically overlap and may be electrically connected to the first access source/drain pattern SDpg1.

Within the first and third memory unit cell regions UC1 and UC3, the fourth source/drain contact plug CAd may vertically overlap and may be electrically connected to the second PMOS source/drain pattern SDpu1b.

Within the first memory unit cell region UC1, the fifth source/drain contact plug CAe may vertically overlap and may be electrically connected to the fourth PMOS source/drain pattern SDpu2b.

Within the first and third memory unit cell regions UC1 and UC3, the sixth source/drain contact plug CAf may vertically overlap and may be electrically connected to the second access source/drain pattern SDpg2.

Within the first memory unit cell region UC1, the seventh source/drain contact plug CAg may vertically overlap the third PMOS source/drain pattern SDpu2a, may extend in the second horizontal direction Y and may vertically overlap the second common source/drain pattern SDnb. The seventh source/drain contact plug CAg may be electrically connected to the third PMOS source/drain pattern SDpu2a and the second common source/drain pattern SDnb.

Within the first memory unit cell region UC1, the eighth source/drain contact plug CAh may vertically overlap the second NMOS source/drain pattern SDpd2 and the third lower separation pattern SPs_Lc, and may be electrically connected to the second NMOS source/drain pattern SDpd2.

Referring to FIG. 4D along with FIGS. 1, 3, 4A to 4C, and 5, gate connection plugs GB and conductive vias VA may be further included.

Within the first circuit region C1, the gate connection plugs GB may include a first gate connection plug GBa, a second gate connection plug GBb, a third gate connection plug GBc, and a fourth gate connection plug GBd.

In the first and second memory unit cell regions UC1 and UC2, the first gate connection plug GBa may vertically overlap the first lower separation pattern SPs_La, the first access gate Gpg1 in the first memory unit cell region UC1, and the first access gate Gpg1 in the second memory unit cell region UC2. In the first and second memory unit cell regions UC1 and UC2, the first gate connection plug GBa may be electrically connected to a gate electrode of the first access gate Gpg1 in the first memory unit cell region UC1 and a gate electrode of the first access gate Gpg1 in the second memory unit cell region UC2. The first gate connection plug GBa may have a bar shape extending in the second horizontal direction Z.

Within the first memory unit cell region UC1, the second gate connection plug GBb may include a first extension portion GBb1 extending in the first horizontal direction X and a second extension portion GBb2 extending from the first extension portion GBb1 in the second horizontal direction Y. The first extension portion GBb1 of the second gate connection plug GBb may vertically overlap the second gate dummy gate Gd2 and the second source/drain contact plug CAb. The second extension portion GBb2 of the second gate connection plug GBb may vertically overlap the second gate dummy gate Gd2, the second lower separation pattern SPs_Ub, and the second PMOS gate Gpu2.

The second gate connection plug GBb may be electrically connected to the second source/drain contact plug CAb and the gate electrode of the second PMOS gate Gpu2.

In the first memory unit cell region UC1, the third gate connection plug GBc may include a first extension portion GBc1 extending in the first horizontal direction X and a second extension portion GBc2 extending from the first extension portion GBc1 in the second horizontal direction Y. The first extension portion GBc1 of the third gate connection plug GBc may vertically overlap the first gate dummy gate Gd1 and the seventh source/drain contact plug CAg. The second extension portion GBc2 of the third gate connection plug GBc may vertically overlap the first gate dummy gate Gd1, the second lower separation pattern SPs_Ub, and the first PMOS gate Gpu1.

The third gate connection plug GBc may be electrically connected to the seventh source/drain contact plug CAg and the gate electrode of the first PMOS gate Gpu1.

Within the first circuit region C1, the conductive vias VA may include source/drain vias VAca, VAcb, VAcc, VAcd, and VAce and gate vias VAga and VAgb. Here, in “source/drain via” and “gate via,” “source/drain via” may refer to a via electrically connected to a source/drain through a source/drain contact plug, and “gate via” refer to a via electrically connected to a gate electrode of the gate through a gate connection plug.

The source/drain vias VAca, VAcb, VAcc, VAcd, and VAce may include a first source/drain via VAca, a second source/drain via VAcb, a third source/drain via VAcc, a fourth source/drain via VAcd, and a fifth source/drain via VAce.

The first source/drain via VAca may be electrically connected to the first source/drain contact plug CAa on the first source/drain contact plug CA, may be disposed in a central region between the first to fourth memory unit cell regions UC1, UC2, UC3, and UC4, and may vertically overlap the first lower separation pattern SPs_La.

The second source/drain via VAcb may be electrically connected to the third source/drain contact plug CAc on the third source/drain contact plug CAc.

The third source/drain via VAcc may be electrically connected to the fourth source/drain contact plug CAd on the fourth source/drain contact plug CAd.

The fourth source/drain via VAcd may be electrically connected to the fifth source/drain contact plug CAe on the fifth source/drain contact plug CAe.

The fifth source/drain via VAce may be electrically connected to the eighth source/drain contact plug CAh on the eighth source/drain contact plug CAh.

The gate vias VAga and VAgb may include a first gate via VAga and a second gate via VAgb.

The first gate via VAga may be electrically connected to the first gate connection plug GBa on the first gate connection plug GBa, and may vertically overlap the first lower separation pattern SPs_La.

The second gate via VAgb may be electrically connected to the fourth gate connection plug GBd on the fourth gate connection plug GBd, and may vertically overlap the third lower separation pattern SPs_Lc.

Referring to FIG. 4E along with FIGS. 1, 3, 4A to 4D, and 5, wiring patterns M1 may be further included.

Within the first circuit region C1, the wiring patterns M1 may include the ground voltage line VSS, the voltage power line VDD, the wordline WL, the first bitline BL1, and the second bitline BL2 described in the circuit diagram in FIG. 3.

The ground voltage line VSS may be referred to as a ground wiring pattern VSS, the voltage power line VDD may be referred to as a power wiring pattern VDD, and the wordline WL may be referred to as a gate wiring pattern WL or a wordline wiring pattern.

Hereinafter, the ground voltage line VSS will be referred to as a ground wiring pattern VSS of SRAM, the voltage power line VDD will be referred to as a power wiring pattern VDD, and the wordline WL will be referred to as a gate wiring pattern WL.

The ground wiring pattern VSS may be electrically connected to the first source/drain via VAca on the first source/drain via VAca. The ground wiring pattern VSS may be disposed in a central region between the first to fourth memory unit cell regions UC1, UC2, UC3, and UC4. The ground wiring pattern VSS may vertically overlap the first lower separation pattern SPs_La, and may have a bar shape extending in the first horizontal direction X.

The gate wiring patterns WL may include a first gate wiring pattern WLa which may be electrically connected to the first gate via VAga on the first gate via VAga, and a second gate wiring pattern WLb which may be electrically connected to the second gate via VAgb. Among the gate wiring patterns WL, gate wiring patterns arranged sequentially in the first horizontal direction X may be electrically connected on a level higher than a level of the gate wiring patterns WL.

The first gate wiring pattern WLa may vertically overlap the first lower separation pattern SPs_La, and may have a bar shape extending in the first horizontal direction X. The second gate wiring pattern WLb may vertically overlap the third lower separation pattern SPs_Lc, and may have a bar shape extending in the first horizontal direction X.

In the description below, an example of the semiconductor device 1 according to example embodiments will be described with reference to FIGS. 6A, 6B, 6C, and 7 along with FIGS. 1, 2, 3, 4A to 4E, and 5 described above.

Referring to FIGS. 1 to 5 and FIGS. 6A, 6B, 6C, and 7, the semiconductor device 1 may further include a base 70, insulating patterns STI on the base 70, and protrusions 70p extending from the base 70 in the vertical direction Z. The base 70 and the protrusions 70p may include an insulating material.

The first and second horizontal directions X and Y described above may be parallel to an upper surface of base 70, and the vertical direction Z may be perpendicular to an upper surface of base 70.

Within the first circuit region C1, the protrusions 70p may be disposed below the source/drain patterns SD and may be in contact with lower surfaces of the source/drain patterns SD.

Within the first circuit region C1, the protrusions 70p may extend in the first horizontal direction X from portions disposed below the source/drain regions SD. For example, one of the protrusions 70p may be disposed below the source/drain patterns SD arranged in the first horizontal direction X and below the gates GATE disposed between the source/drain patterns SD.

Within the second circuit region C2, the protrusions 70p may be disposed on both side surfaces of the peripheral lower separation pattern SPL_L and below the first and second peripheral gates G_La and G_Lb.

Each of the lower separation patterns SPs_L may include first portions in contact with the source/drain patterns SD and second portions extending from the first portions and in contact with the gates GATE and the channel regions CH.

For example, the first lower separation pattern SPs_La may include first portions SP_LL1 and SP_LU1 in contact with the first common source/drain pattern SDna and the first NMOS source/drain pattern SDpd1, and second portions SP_LL2 and SP_LU2 extending from the first portions SP_LL1 and SP_LU1 and in contact with the first access gate Gpg1, the first access channel regions CHpg1, the first NMOS gate Gpd1, and the first NMOS channel regions CHpd1.

The peripheral lower separation pattern SPL_L may include a first portion SP_LL1 and SP_LU1 in contact with the first and second peripheral source/drain patterns SD_La and SD_Lb and a second portion SP_LL2 and SP_LU2 in contact with the first and second peripheral gates G_La and G_Lb.

Each of the lower separation patterns SPs_L may include lower separation regions SP_LL1 and SP_LL2 disposed on substantially the same level as the protrusions 70p and upper separation region SP_LU1 disposed on a level higher than a level of the protrusions 70p on the lower separation region SP_LL1 and SP_LL2. In the lower separation patterns SPs_L, regions in contact with the protrusions 70p may be defined as the lower separation regions SP_LL1 and SP_LL2.

Each of the lower separation patterns SPs_L may be disposed between a pair of insulating patterns STI adjacent to each other. The protrusions 70p in contact with the lower separation regions SP_LL1 and SP_LL2 and the lower separation regions SP_LL1 and SP_LL2 of the lower separation patterns SPs_L may be disposed between the insulating patterns STI.

Each of the first portions SP_LL1 and SP_LU1 of the first lower separation pattern SPs_La may include a first lower separation region SP_LL1 and a first upper separation region SP_LU1 on the first lower separation region SP_LL1, and each of the second portions SP_LL2 and SP_LU2 of the first lower separation pattern SPs_La may include a second lower separation region SP_LL2 and a second upper separation region SP_LU2 on the second lower separation region SP_LL2.

The upper separation patterns SPs_U may be disposed on the lower separation patterns SPs_U. Among the upper separation patterns SPs_U and the lower separation patterns SPs_U in contact with each other, a side surface of the upper separation pattern SPs_U may not be aligned with a side surface of the lower separation pattern SPs_L.

In an example, among the upper separation patterns SPs_U and the lower separation patterns SPs_U in contact with each other, the upper separation pattern SPs_U may have a downwardly curved shape extending into an upper region of the lower separation pattern SPs_L. That is, the upper separation pattern SPs_U may have a downwardly curved lower surface, and the lower separation pattern SPs_L may have a downwardly recessed upper surface. However, an example embodiment thereof is not limited thereto. For example, the upper separation pattern SPs_U may have an upwardly recessed lower surface, and the lower separation pattern SPs_L may have an upwardly curved upper surface.

Each of the channel regions CH may include channel layers CHa, CHb, CHc, and CHd stacked and spaced apart from each other in the vertical direction Z. For example, each of the channel regions CH may include a first channel layer CHa, a second channel layer CHb, a third channel layer CHc, and a fourth channel layer CHd, which are sequentially stacked.

Each of the channel layers CHa, CHb, CHc, and CHd may include a semiconductor material, for example, a silicon material which may be used as a channel region of a transistor.

Each of the gates GATE may include a gate dielectric layer Gox and gate electrodes GE1 and GE2 on the gate dielectric layer Gox.

The gate dielectric layer Gox may include at least one of silicon oxide and high-K dielectric. The high-K dielectric may refer to a dielectric having a dielectric constant higher than that of a silicon oxide film (SiO₂). The high-K dielectric may include at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrodes GE1 and GE2 may include a first gate electrode GE1 in contact with the gate dielectric layer Gox and a second gate electrode GE2 on the first gate electrode GE1. The first gate electrode GE1 may be a work-function control material layer, and the second gate electrode GE2 may include a conductive material having resistivity lower than a material of the first gate electrode GE1. For example, the first gate electrode GE1 may include at least one of TiN, TaN, WN, NbN, TiAl, TiAIN, TiSi, TiSiN, TaSiN, and RuTiN, and the second gate electrode GE2 may include at least one of Ti, Ta, Ru, W, Mo, Pt, Ni, and Co. The material type and a thickness of the first gate electrode GE1 may be varied depending on the NMOS transistor and the PMOS transistor.

The semiconductor device 1 may further include gate capping patterns 45 disposed on upper surfaces of the gates GATE and disposed on upper surfaces of the lower separation patterns SPs_L adjacent to the gates GATE. The gate capping patterns 45 may be disposed on the gates GATE and may vertically overlap the lower separation patterns SPs_L. Upper surfaces of the gate capping patterns 45 may be disposed on substantially the same level as upper surfaces of the upper separation patterns SPs_U. The gate capping patterns 45 may include an insulating material such as silicon nitride.

In the first lower separation pattern SDs_La, the first upper separation region SP_LU1 of the first portion SP_LL1 and SP_LU1 in contact with the first source/drain patterns SDpd1 may be disposed between the first source/drain pattern SDpd1 of the first memory unit cell region UC1 and the first source/drain pattern SDpd1 of the second memory unit cell region UC2.

The source/drain patterns SD may further include a source/drain extension pattern SDpde extending from the first source/drain pattern SDpd1 of the first memory unit cell region UC1 and the first source/drain pattern SDpd1 of the second memory unit cell region UC2, and covering an upper surface of the first upper separation region SP_LU1 of the first portion SP_LL1 and SP_LU1 of the first lower separation pattern SDs_La. The source/drain extension pattern SDpde may extend from the first source/drain pattern SDpd1 of the first memory unit cell region UC1 and the first source/drain pattern SDpd1 of the second memory unit cell region UC2, and may extend to between the first source/drain contact plug CAa and an upper surface of the first upper separation region SP_LU1. The first source/drain contact plug CAa may also be referred to as a common source/drain contact plug.

The first source/drain pattern SDpd1 of the first memory unit cell region UC1, the first source/drain pattern SDpd1 of the second memory unit cell region UC2, and the source/drain extension pattern SDpde may include a source/drain epitaxial layer continuously connected. Accordingly, the first source/drain pattern SDpd1 of the first memory unit cell region UC1, the first source/drain pattern SDpd1 of the second memory unit cell region UC2, and the source/drain extension pattern SDpde may form a source/drain pattern.

The source/drain extension pattern SDpde may be in contact with the upper surface of the first upper separation region SP_LU1 of the first portion SP_LL1 and SP_LU1 of the first lower separation pattern SDs_La.

Upper ends of the source/drain patterns SD may be disposed on a level higher than a level of an upper surface of the first upper separation region SP_LU1 and lower ends of the upper separation patterns SPs_U.

Upper ends of the source/drain patterns SD may be disposed at a level lower than an upper surface of the second upper separation region SP_LU2.

Upper ends of the source/drain patterns SD may be disposed on a level lower than a level of upper surfaces of the gates GATE.

Among the source/drain patterns SD, each of the first PMOS source/drain pattern SDpu1a, the second PMOS source/drain pattern SDpu1b, the third PMOS source/drain pattern SDpu2a and the fourth PMOS source/drain pattern SDpu2b having P-type conductivity may include a first epitaxial layer EP1 and a second epitaxial layer EP2 on the first epitaxial layer EP1. The first epitaxial layer EP1 may be a Si epitaxial layer or a SiGe epitaxial layer, and the second epitaxial layer EP2 may include a SiGe epitaxial layer having a Ge concentration different from that of the first epitaxial layer EP1.

Among the source/drain patterns SD, the first NMOS source/drain pattern SDpd1, the first common source/drain pattern SDna, the second NMOS source/drain pattern SDpd2, the second common source/drain pattern SDnb, the first access source/drain pattern SDpg1, and the second access source/drain pattern SDpg2 having N-type conductivity may include a Si epitaxial material layer.

In the first lower separation pattern SDs_La, the second upper separation region SP_LU2 of the second portion SP_LL2 and SP_LU2 in contact with the first access gates Gpg1 may be disposed between the first access gate Gpg1 of the first memory unit cell region UC1 and the first access gate Gpg1 of the second memory unit cell region UC2.

In each of the lower separation patterns SPs_L, a lower surface of the first lower separation region SP_LL1 and a lower surface of the second lower separation region SP_LL2 may be disposed on substantially the same level.

In each of the lower separation patterns SPs_L, an upper surface of the second upper separation region SP_LU2 may be disposed on a level higher than a level of an upper surface of the first upper separation region SP_LU1.

In the first lower separation pattern SDs_La, the second upper separation region SP_LU2 of the second portion SP_LL2 and SP_LU2 in contact with the first access gates Gpg1 may be in contact with the gate dielectric layers Gox and the first access channel region CHpg1 of the first access gates Gpg1.

Each of the channel layers CHa, CHb, CHc, and CHd may have a first side surface in contact with the second upper separation region SP_LU2 of the lower separation pattern SPs_L adjacent thereto, and a second side surface opposing the first side surface and in contact with the gate dielectric layer Gox. Each of the channel layers CHa, CHb, CHc, and CHd may include a semiconductor material, for example, silicon.

In each of the first access gates Gpg1, the gate dielectric layer Gox may cover upper and lower surfaces of the channel layers CHa, CHb, CHc, and CHd, may cover the second side surfaces opposing the first side surfaces in contact with the second upper separation region SP_LU2 among the side surfaces of the channel layers CHa, CHb, CHc, and CHd, and may be in contact with a side surface of the second upper separation region SP_LU2 not in contact with the channel layers CHa, CHb, CHc, and CHd.

In each of the first access gates Gpg1, the first gate electrode GE1 of the gate electrodes GE1 and GE2 in contact with the gate dielectric layer Gox may be a work-function control electrode.

In each of the first access gates Gpg1, the first gate electrode GE1 of the gate electrodes GE1 and GE2 in contact with the gate dielectric layer Gox may include extension portions extending to a region between the channel layers CHa, CHb, CHc, and CHd, and a lower extension portion extending to a region between the first channel layer CHa and the protrusion 70p.

A portion of the source/drain patterns SD may be in contact with a side surface of a lower region of the upper separation pattern SPs_U. For example, the second PMOS source/drain pattern SDpu1b may be in contact with an upper surface of the protrusion 70p, a side surface of an upper region of the first lower separation pattern SPs_Lb, and a side surface of a lower region of the second upper separation pattern SPs_Ub. The first common source/drain patterns SDna of the first and second memory unit cell regions UC1 and UC2 may be in contact with upper surfaces of the protrusions 70p.

The semiconductor device 1 may further include an interlayer insulating layer 33.

The interlayer insulating layer 33 may be disposed on the insulating pattern STI and the source/drain patterns SD. The interlayer insulating layer 33 may have an upper surface coplanar with upper surfaces of the upper separation patterns SPs_U.

The source/drain contact plugs CA may penetrate the interlayer insulating layer 33 and may be in contact with the source/drain patterns SD. Upper surfaces of the source/drain contact plugs CA may be disposed on substantially the same level as upper surfaces of the upper separation patterns SPs_U and an upper surface of the interlayer insulating layer 33. The source/drain contact plugs CA may be disposed on the source/drain patterns SD and may be in contact with the source/drain patterns SD. The source/drain contact plugs CA may be spaced apart from the lower separation patterns SPs_L.

For example, the first source/drain contact plug CAa may be in contact with the source/drain extension pattern SDpde and may be electrically connected to the source/drain extension pattern SDpde. Accordingly, the first source/drain contact plug CAa may be electrically connected to the first NMOS source/drain pattern SDpd1 of the first and third memory unit cell regions UC1 and UC3 and the first NMOS source/drain pattern SDpd1 of the second and fourth memory unit cell regions UC2 and UC3 through the source/drain extension pattern SDpde.

Within each of the first and second memory unit cell regions UC1 and UC2, the second source/drain contact plug CAb may be disposed on the first common source/drain pattern SDna and the first PMOS source/drain pattern SDpu1a and may be in contact with and electrically connected to the first common source/drain pattern SDna and the first PMOS source/drain pattern SDpu1a. The second source/drain contact plug CAb of the first memory unit cell region UC1 and the second source/drain contact plug CAb of the second memory unit cell region UC2 may be spaced apart from each other by the first upper separation pattern SPs_Ua.

The semiconductor device 1 may further include an insulating liner 30. The insulating liner 30 may be formed of a material different from that of the interlayer insulating layer 33 and the insulating patterns STI. For example, the interlayer insulating layer 33 and the insulating patterns STI may include at least one of silicon oxide and low-K dielectric, and the insulating liner 30 may include at least one of SiN, SiCN, and SiBN.

The insulating liner 30 may include a portion disposed between the interlayer insulating layer 33 and the source/drain patterns SD, between the interlayer insulating layer 33 and the insulating patterns STI, between the interlayer insulating layer 33 and the lower separation patterns STI, and between the interlayer insulating layer 33 and the upper separation patterns between SPs_U. The insulating liner 30 may further include a portion disposed between the source/drain contact plugs CA and the upper separation patterns SPs_U. The insulating liner 30 may further include a portion disposed on side surfaces of the gates GATE disposed on a level higher than a level of the source/drain patterns SD on the source/drain patterns SD, and disposed on side surfaces of the gate capping patterns 45.

The semiconductor device 1 may further include an insulating spacer 21 disposed between the insulating liner 30 and the side surfaces of the gates GATE disposed at a higher level than the source/drain patterns SD on the source/drain patterns SD, and extending to a region between the insulating liner 30 and the lower separation patterns SPs_L. The insulating spacer 21 may be disposed below the gate capping patterns 45.

The second upper separation pattern SPs_Ub adjacent to the fourth source/drain contact plug CAd may include a lower side surface in contact with the fourth source/drain contact plug CAd and an upper side surface in contact with the insulating liner 30.

The semiconductor device 1 may further include contact separation patterns 54 disposed on the insulating patterns STI and allowing the source/drain contact plugs CA to be spaced apart from each other on the insulating patterns STI. For example, one of the contact separation patterns 54 may pass between the first source/drain contact plug CAa and the fourth source/drain contact plug Cad, may extend into the interlayer insulating layer 33, may allow the first source/drain contact plug CAa and the fourth source/drain contact plug CAd to be spaced apart from each other. The contact separation patterns 54 may include an insulating material such as silicon nitride.

The gate connection plugs GB may be in contact with the gate electrodes GE1 and GE2 of the gates GATE and may be electrically connected to the gate electrodes GE1 and GE2. For example, in the first and second memory unit cell regions UC1 and UC2, the first gate connection plug GBa may be disposed on the first lower separation pattern SPs_La, the first access gate Gpg1 in the first memory unit cell region UC1, and the first access gate Gpg1 in the second memory unit cell region UC2. The first gate connection plug GBa may be in contact with an upper surface of the first lower separation pattern SPs_La, upper surfaces of the gate electrodes GE1 and GE2 of the first access gates Gpg1, and upper ends of the gate dielectric layers Gox.

The semiconductor device 1 may further include gate separation patterns 48. The gate separation patterns 48 may be disposed on the insulating patterns STI. The gate separation patterns 48 may pass between the first access gate Gpg1 and the second dummy gate Gd2, and between the second access gate Gpg1 and the first dummy gate Gd1, may extend upwardly, may penetrate the gate capping patterns 45, may extend downwardly, and may extend into the insulating patterns STI. The gate separation patterns 48 may include an insulating material such as silicon nitride. A lower surface of the gate separation patterns 48 may be disposed on a level lower than a level of a lower surface of the contact separation patterns 54.

The semiconductor device 1 may further include a first intermetallic insulating layer 60 and a second intermetallic insulating layer 63 on the first intermetallic insulating layer 60.

The first intermetallic insulating layer 60 may be disposed on the source/drain contact plugs CA, the gate connection plugs GB, the gate capping patterns 45, and the upper separation patterns SPs_U.

The conductive vias VA described above with reference to FIG. 4D may penetrate the first intermetallic insulating layer 60 and may be electrically connected to the source/drain contact plugs CA and the gate connection plugs GB.

The wiring patterns VSS, VDD, WL, BL1, and BL2 described above with reference to FIG. 4E may penetrate the second intermetallic insulating layer 60 and may be electrically connected to the conductive vias VA.

The semiconductor device 1 may further include a backside insulating layer 90 below the base 70.

Within the second circuit region C2, the semiconductor device 1 may further include a lower peripheral source/drain contact plug 85, and a backside wiring pattern 95.

The lower peripheral source/drain contact plug 85 may penetrate the base 70, may extend upwardly, and may be electrically connected to the first peripheral source/drain pattern SD_La.

An upper surface of the lower peripheral source/drain contact plug 85 may be in contact with a lower surface of the first peripheral source/drain pattern SD_La. The lower peripheral source/drain contact plug 85 may be in contact with one of side surfaces of the lower separation region SP_LL1 of the peripheral lower separation pattern SPL_L.

The backside wiring pattern 95 may be disposed in the backside insulating layer 90 and may be electrically connected to the lower peripheral source/drain contact plug 85.

The source/drain contact plugs CA described above may include upper peripheral source/drain contact plugs CApa and CApb disposed in the second circuit region C2. The conductive vias VA described above may include a peripheral via VAp disposed in the second circuit region C2. The wiring patterns M1 described above may include a peripheral wiring pattern Mp disposed in the second circuit region C2.

The upper peripheral source/drain contact plugs CApa and CApb may include a first upper peripheral source/drain contact plug CApa disposed on the first peripheral source/drain pattern SD_La and a second upper peripheral source/drain contact plug CApb disposed on the second peripheral source/drain pattern SD_Lb. The first upper peripheral source/drain contact plug CApa may be in contact with the first peripheral source/drain pattern SD_La, and the second upper peripheral source/drain contact plug CApb may be in contact with the second peripheral source/drain pattern SD_Lb.

The entire upper surface of the first upper peripheral source/drain contact plug CApa may be in contact with an insulating material and may not be connected to the conductive vias VA. For example, the entire upper surface of the first upper peripheral source/drain contact plug CApa may be in contact with the first intermetallic insulating layer 60.

Among the contact separation patterns 54, a contact separation pattern formed in the second circuit region C2 may be referred to as peripheral contact separation patterns 54p. The peripheral contact separation patterns 54p may be in contact with side surfaces of the upper peripheral source/drain contact plugs CApa and CApb and may extend downwardly.

The peripheral via VAp may be disposed on the second peripheral source/drain contact plug CApb, and the peripheral wiring pattern Mp may be disposed on the peripheral via VAp. Accordingly, the first peripheral source/drain pattern SD_La may be electrically connected to the backside wiring pattern 95 through the lower peripheral source/drain contact plug 85, and the second peripheral source/drain pattern SD_Lb may be electrically connected to the peripheral wiring pattern Mp through the second upper peripheral source/drain contact plug CApb and the peripheral via VAp.

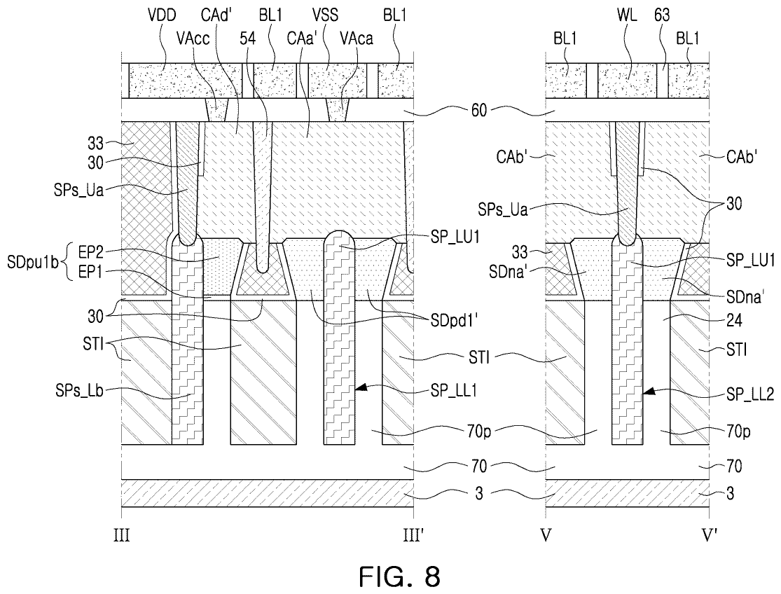

Hereinafter, various modified examples of the above-described example embodiment to increase integration density and to improve reliability of the semiconductor device 1 will be described with reference to FIGS. 8 to 11. Various modified examples of the elements of the above-described example embodiment described below will be described based on modified elements, replaced elements, or added elements. Also, the elements which may be modified or replaced will be described with reference to the drawings, but the elements which may be modified or replaced may be combined with each other or with the elements described above and may form a semiconductor device according to an example embodiment.

FIG. 8 is a cross-sectional diagram illustrating a region taken along line III-III′ and line V-V′ in FIG. 1, illustrating a modified example of the source/drain contact plugs CA and the source/drain patterns SD on a cross-sectional surface taken along line III-III′ in FIG. 6B and a cross-sectional surface taken along line V-V′ in FIG. 6C.

Referring to FIG. 8, the source/drain contact plugs CA described above may be modified to source/drain contact plugs in contact with the lower separation patterns SPs_L, and the source/drain patterns SD in contact with such source/drain contact plugs may be modified to drain patterns having an upper surface disposed on a level lower than a level of an upper surface of the first portions SP_LL1 and SP_LU1 of the lower separation patterns SPs_L.

For example, the first source/drain contact plug CAa described above may be modified to “first source/drain contact plug CAa” in contact with an upper surface of the first lower separation pattern SPs_La, and the first NMOS source/drain patterns SDpd1 in contact with the first source/drain contact plug CAa may be modified to first NMOS source/drain patterns SDpd1′ having an upper surface disposed on a level lower than a level of an upper surface of the first portion SP_LL1 and SP_LU1 of the first lower separation pattern SPs_La. Here, the source/drain extension pattern (SDpde in FIG. 5B) described above may not be provided.

The second source/drain contact plugs CAb described above may be modified to second source/drain contact plugs CAb′ in contact with an upper surface of the first lower separation pattern SPs_La, and the first common source/drain patterns SDna described above may be modified to “first common source/drain patterns SDna” having an upper surface disposed on a level lower than a level of an upper surface of the first portion SP_LL1 and SP_LU1 of the first lower separation pattern SPs_La.

The fourth source/drain contact plugs CAd described above may be modified to fourth source/drain contact plugs CAd′ in contact with an upper surface of the first lower separation pattern SPs_La, and the second PMOS source/drain pattern SDpu1b described above may be modified to a second PMOS source/drain pattern SDpu1b′ having an upper surface disposed on a level lower than a level of an upper surface of the first portion SP_LL1 and SP_LU1 of the first lower separation pattern SPs_La.

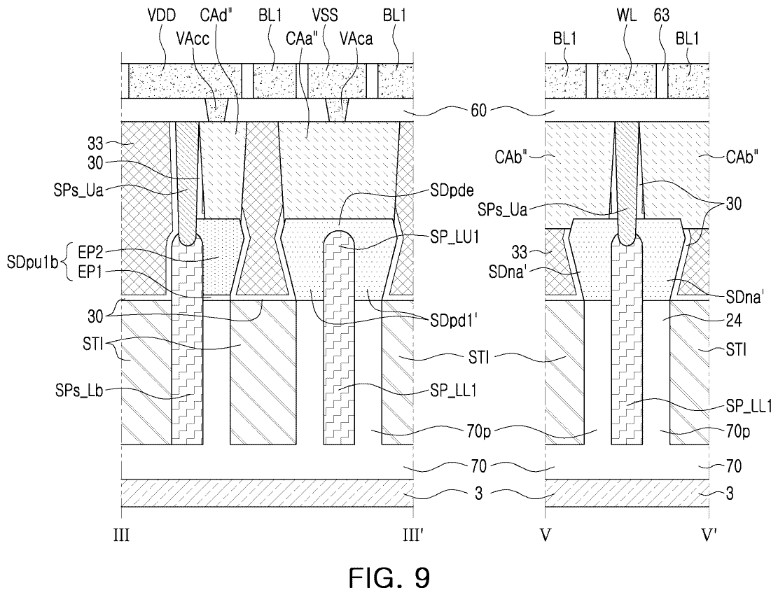

FIG. 9 is a cross-sectional diagram illustrating a region taken along lines III-III′ and V-V′ in FIG. 1, illustrating a modified example of the source/drain contact plugs CA in a cross-sectional surface taken along line III-III′ in FIG. 6B and a cross-sectional surface taken along line V-V′ in FIG. 6C.

Referring to FIG. 9, the source/drain contact plugs CA described above may be modified to source/drain contact plugs having a width decreases downwardly.

For example, the first source/drain contact plug CAa and the fourth source/drain contact plug CAd described above may be modified to a first source/drain contact plug CAa″ and a fourth source/drain contact plug CAd″ having a width decreases downwardly. A portion of the interlayer insulating layer 33 may extend to a region between the first source/drain contact plug CAa″ and the contact separation pattern 54, and may extend into a region between the fourth source/drain contact plug CAd″ and the contact separation pattern 54.

The second source/drain contact plugs CAb described above may be modified to second source/drain contact plugs CAb″ having a width decrease downwardly. A distance between the second source/drain contact plugs CAb″ adjacent to each other may increase downwardly.

In an example embodiment, the contact separation pattern (54 in FIG. 6B) described above may not be provided.

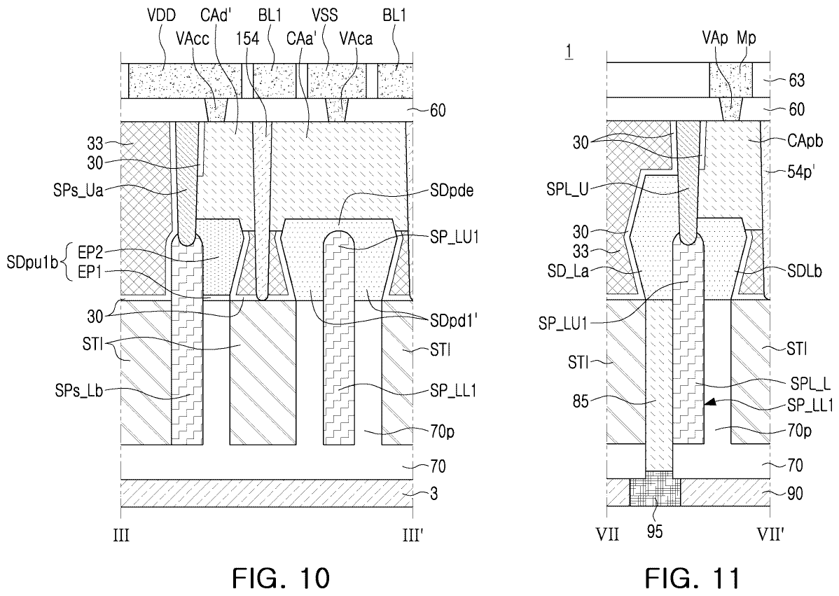

FIG. 10 is a cross-sectional diagram illustrating a region taken along line III-III′ in FIG. 1, illustrating a modified example of the contact separation pattern 54 in a cross-sectional surface taken along line III-III′ in FIG. 6B.

Referring to FIG. 10, the contact separation pattern 54 described above may be modified to a contact separation pattern 154 passing between the first and fourth source/drain contact plugs CAa and CAd, penetrating the interlayer insulating layer 33, and in contact with the insulating liner 30. A lower end of the contact separation pattern 154 may be in contact with the insulating pattern STI.

FIG. 11 is a cross-sectional diagram illustrating a region taken along line VII-VII′ in FIG. 2, illustrating a modified example of a cross-sectional surface taken along line VII-VII′ in FIG. 7.

Referring to FIG. 11, the first upper peripheral contact plug (CApa in FIG. 7) described in FIG. 7 may not be provided. An upper surface of the first peripheral source/drain pattern SD_La may be disposed on a level higher than a level of the upper surface of the second peripheral source/drain pattern SD_Lb. The entire upper surface of the first peripheral source/drain pattern SD_La may be in contact with an insulating material, for example, the insulating liner 30. Accordingly, the upper surface of the first peripheral source/drain pattern SD_La may be in contact with the insulating liner 30, and a lower surface of the first peripheral source/drain pattern SD_La may be in contact with the peripheral source/drain contact plug 85.

The contact separation pattern 54p described above may be modified to a contact separation pattern 54p′ in contact with the upper peripheral source/drain contact plugs CApa and CApb, extending downwardly, penetrating the interlayer insulating layer 33, and in contact with the insulating liner 30. A lower end of the contact separation pattern 54′ may be in contact with the insulating pattern STI.

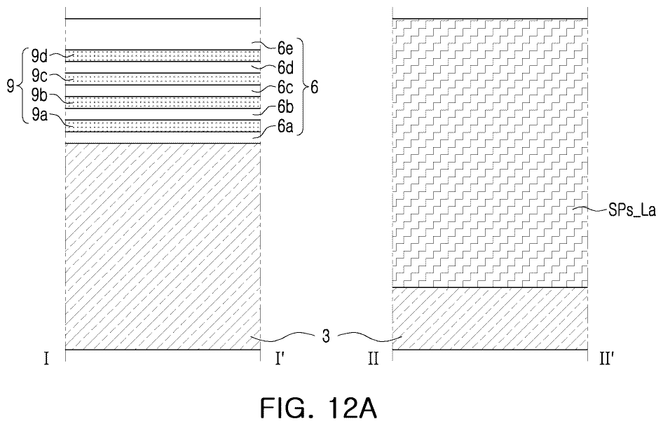

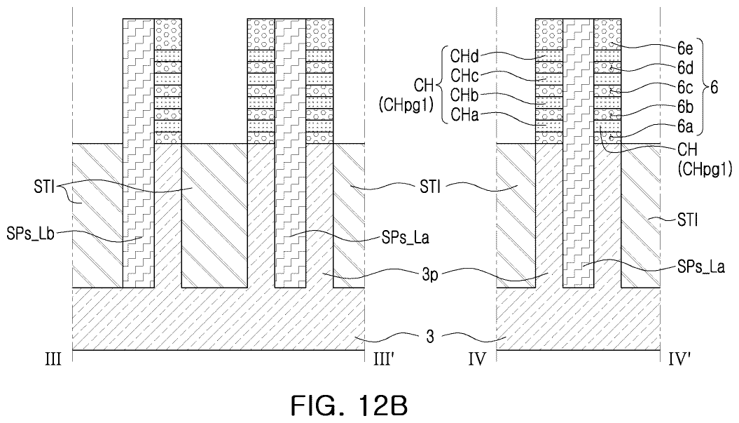

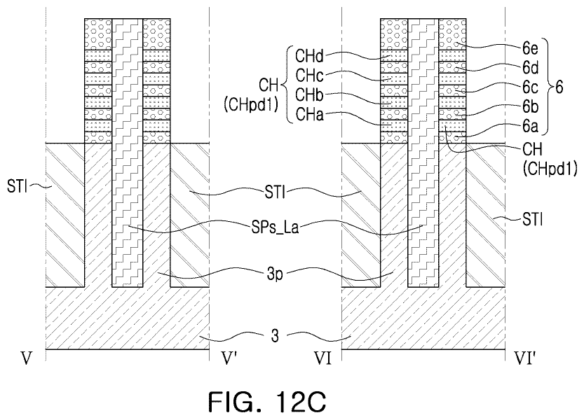

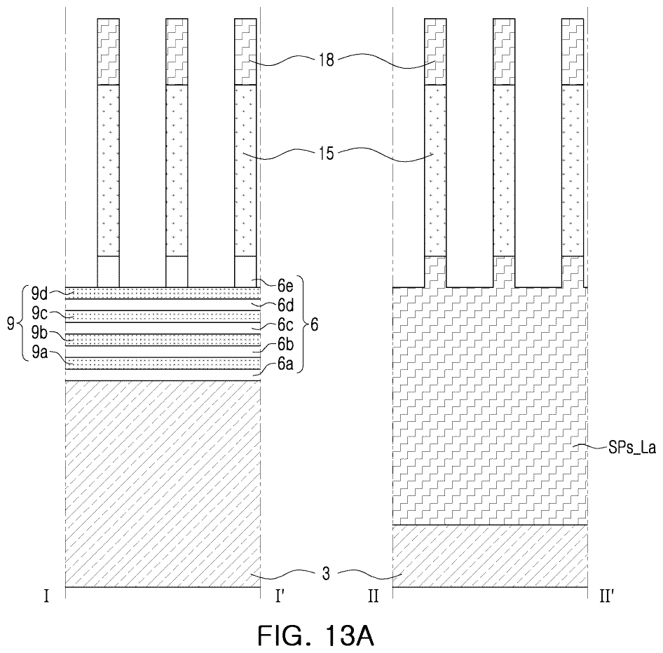

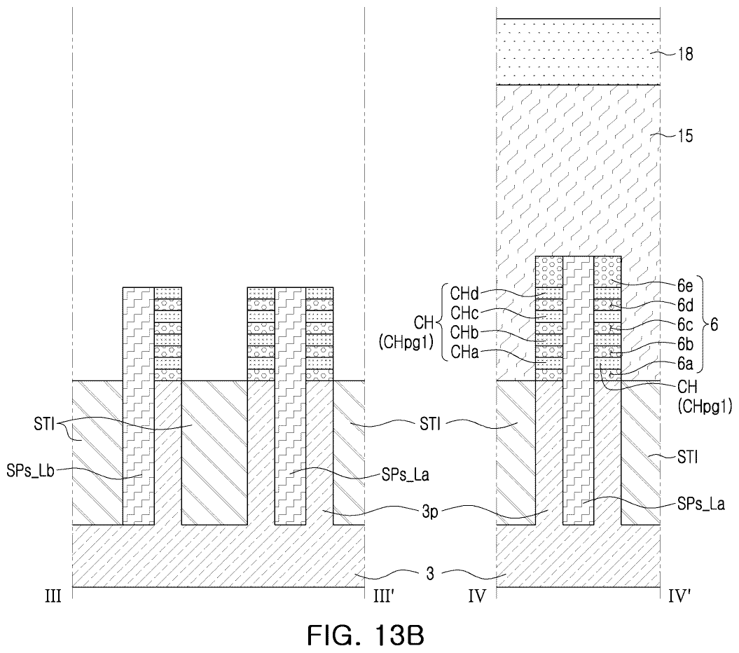

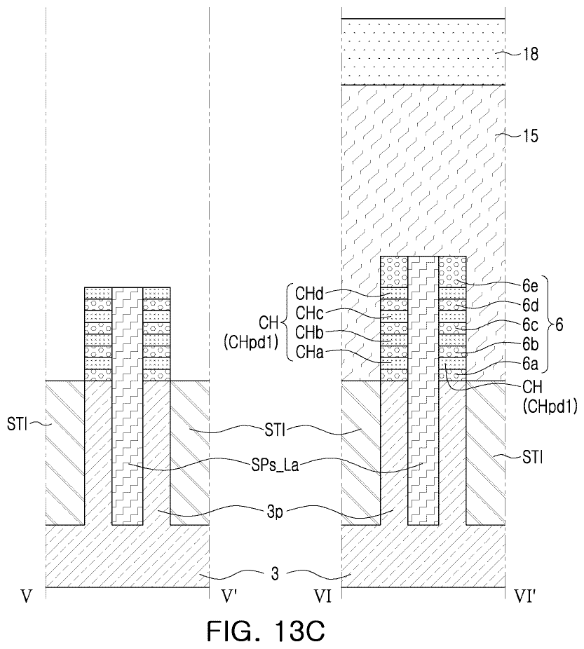

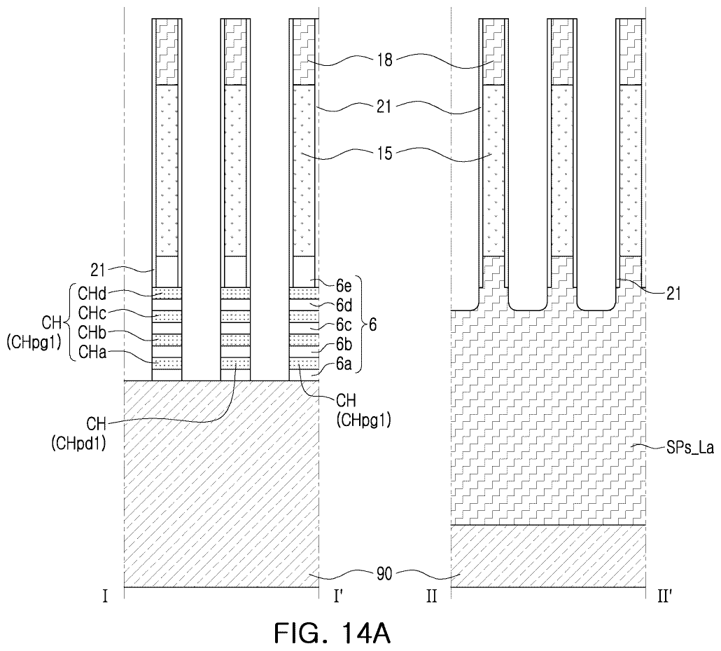

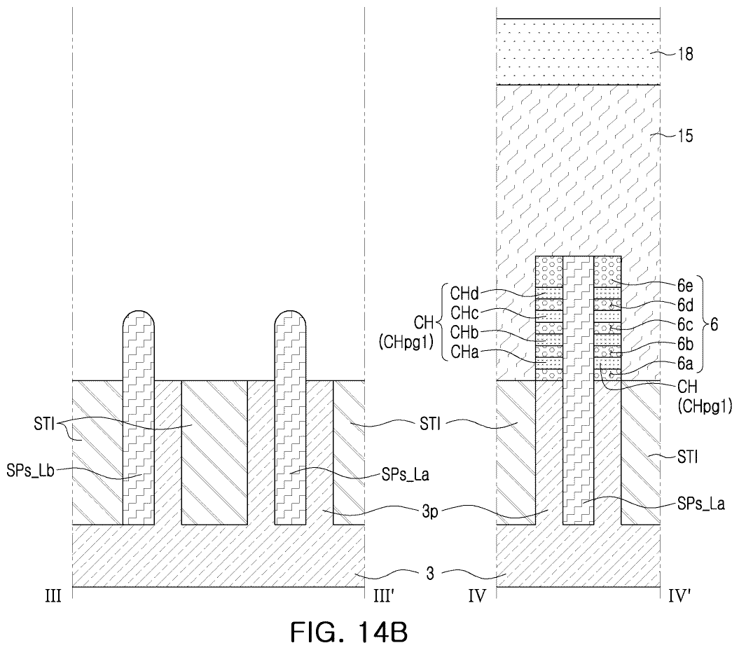

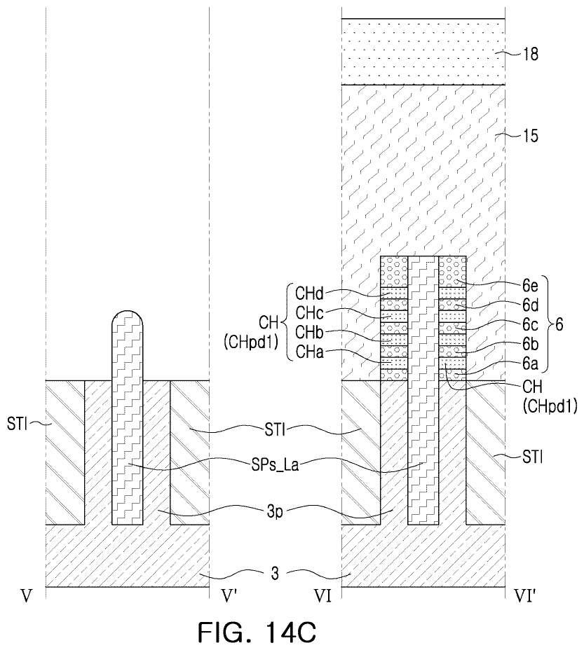

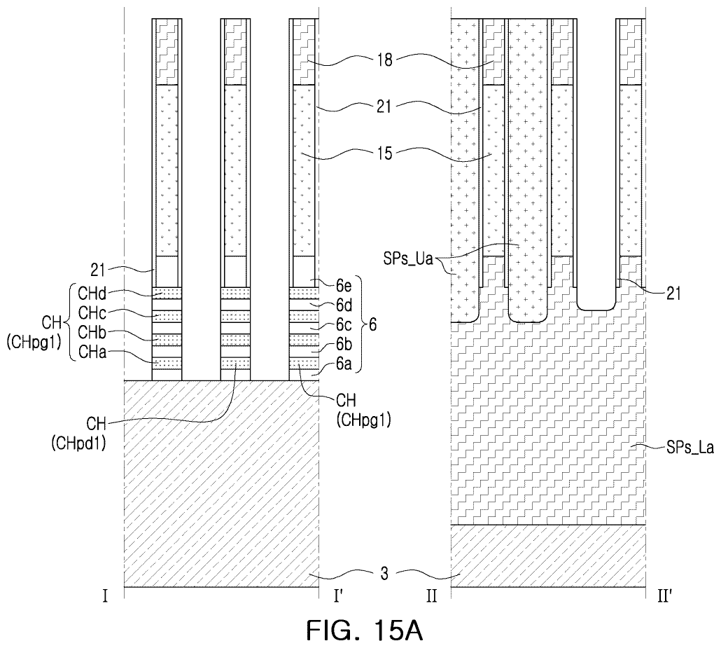

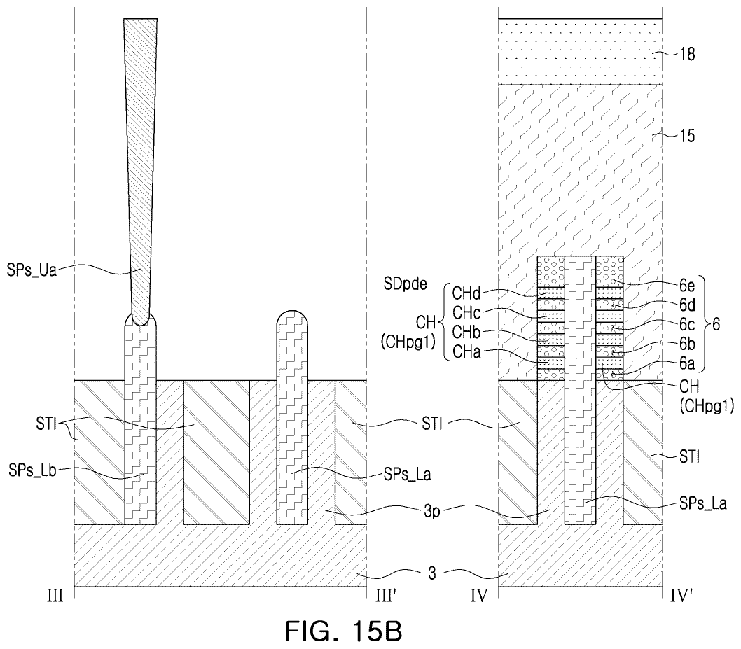

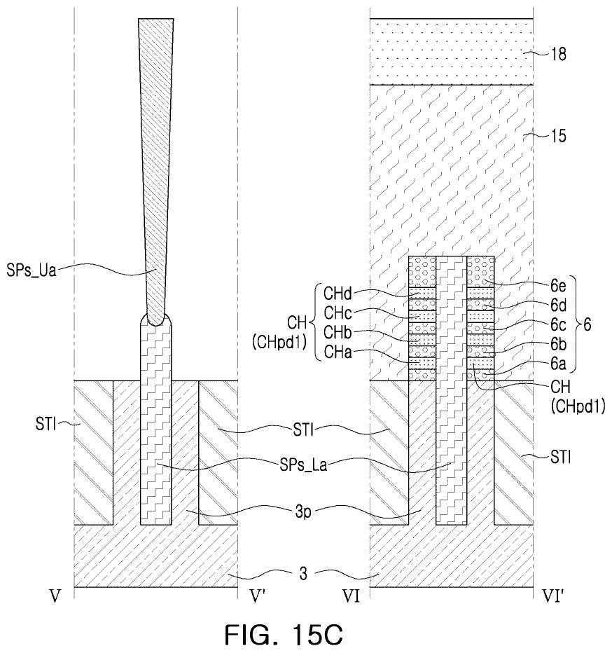

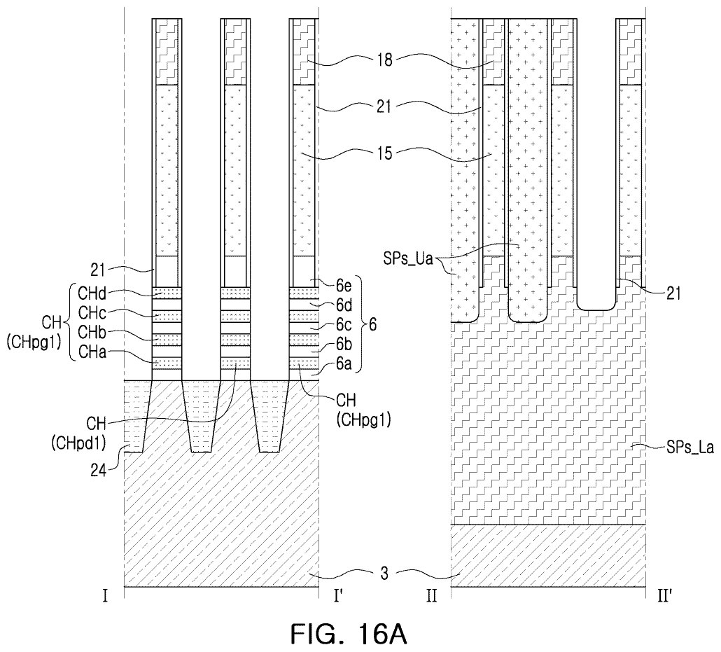

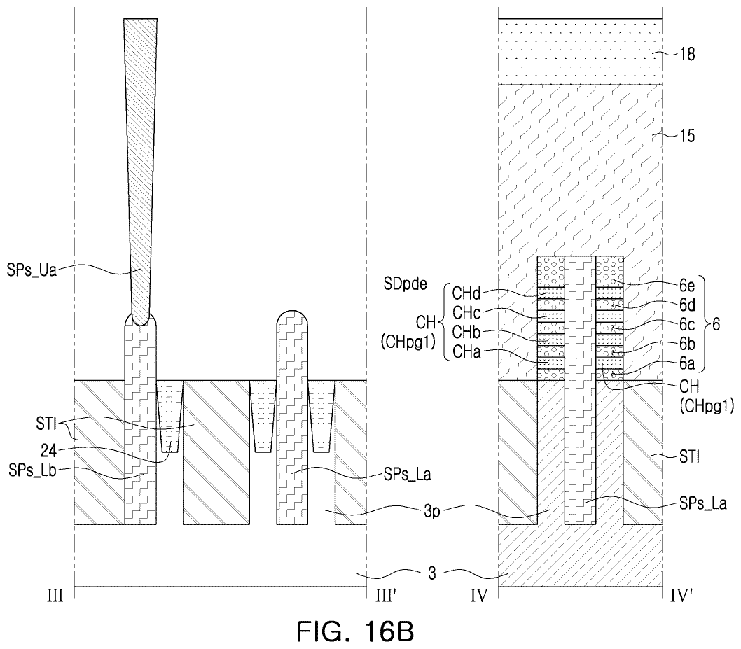

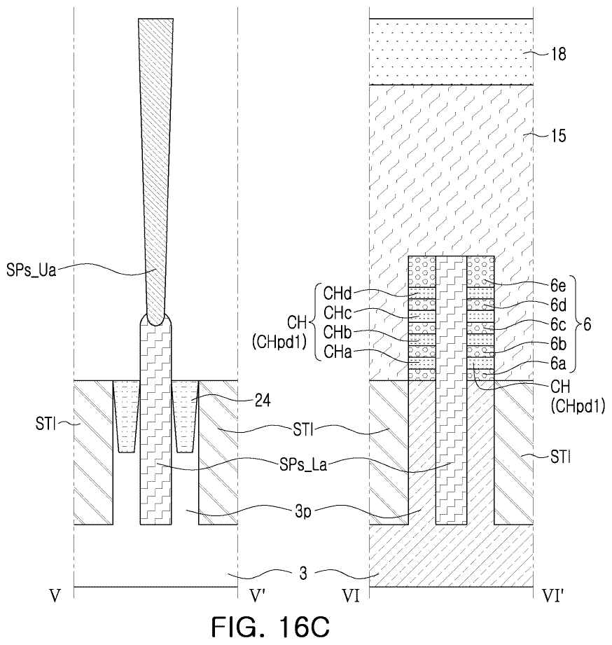

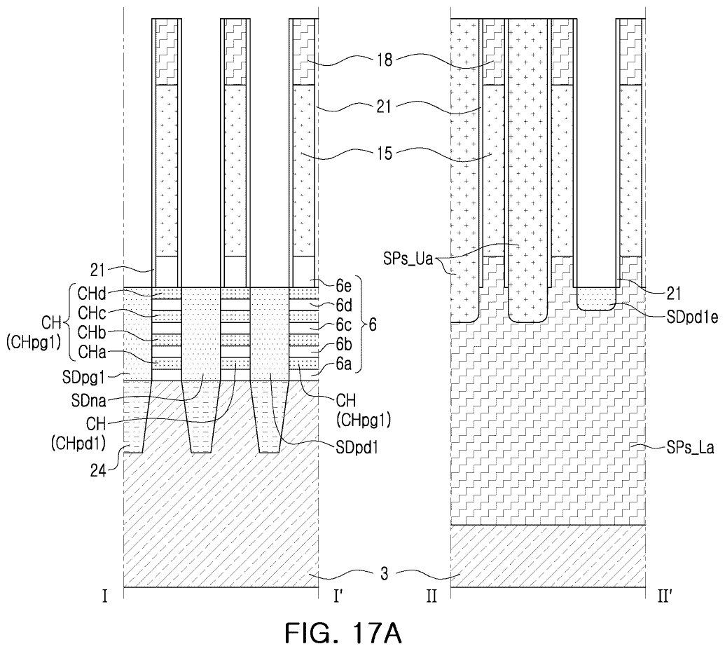

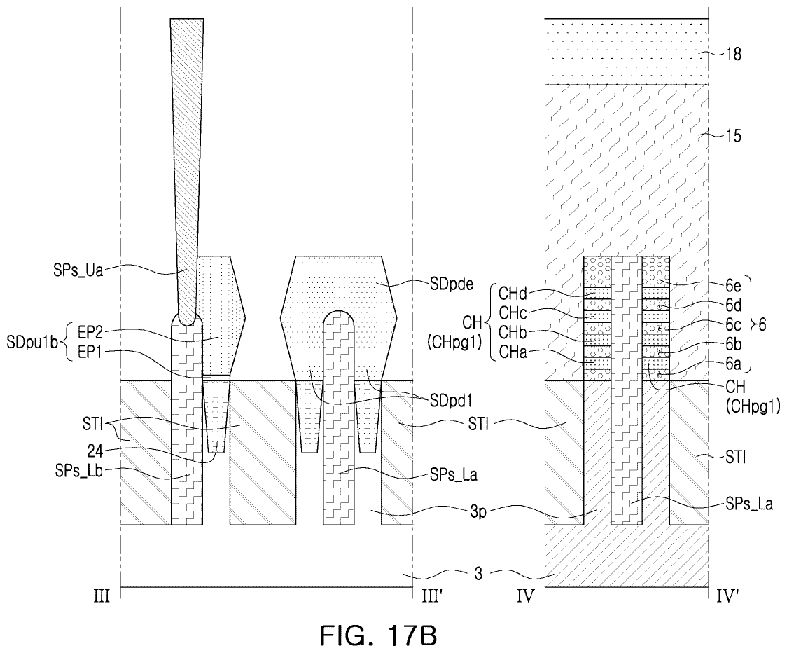

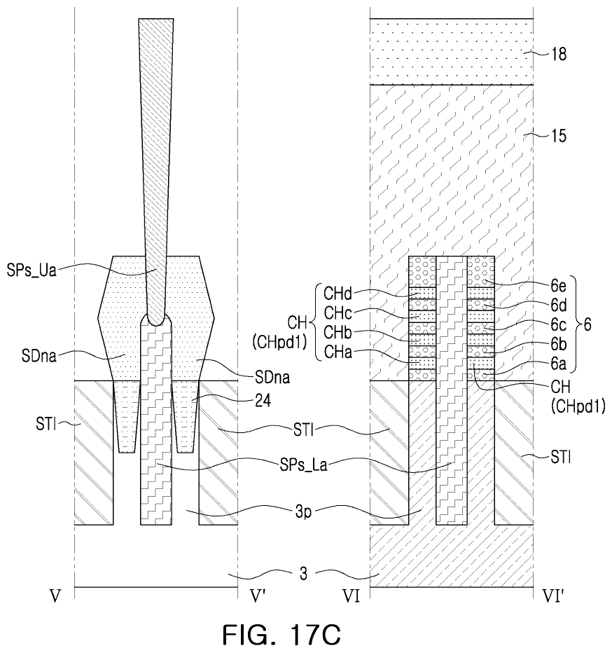

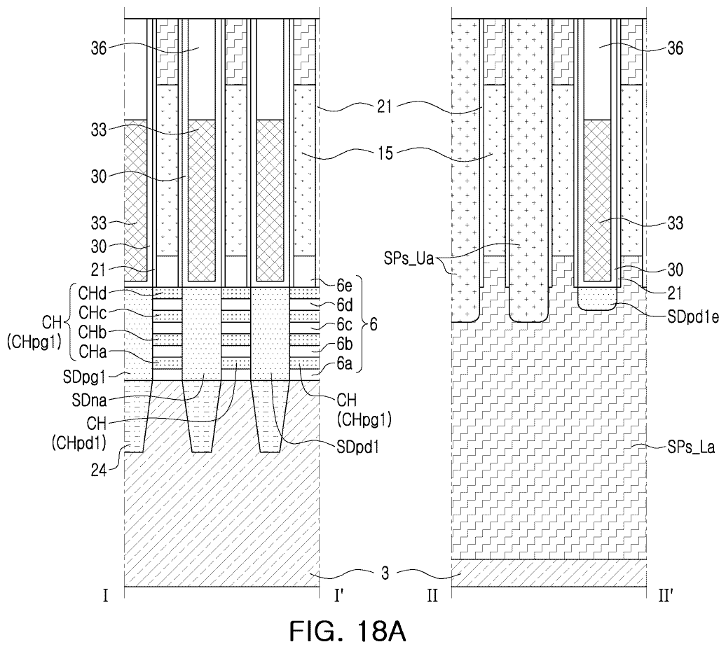

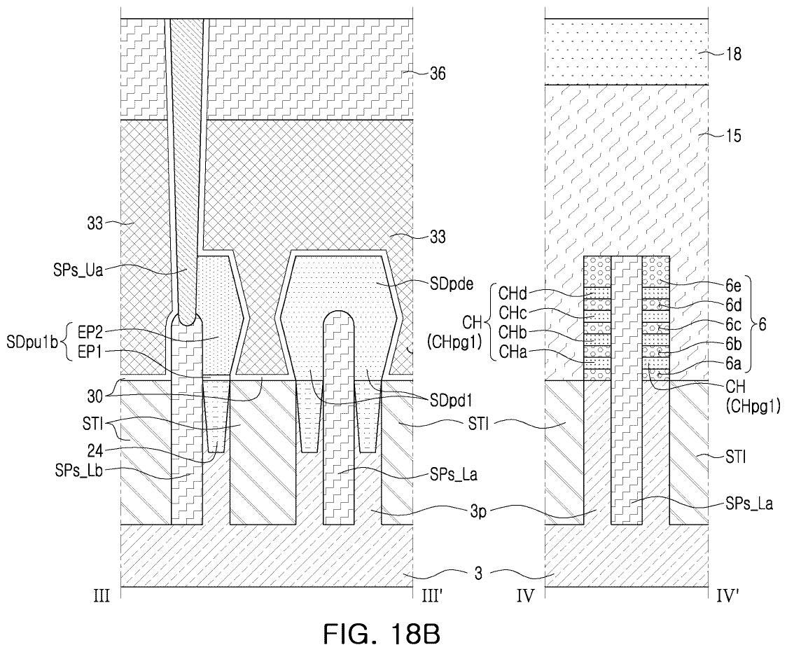

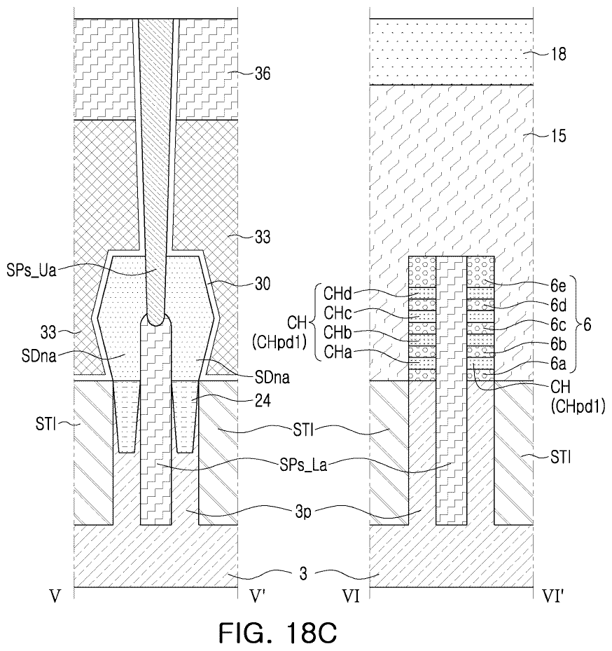

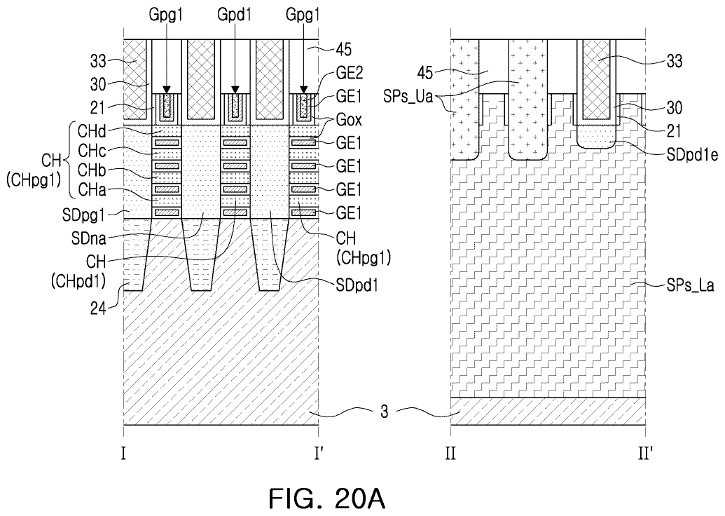

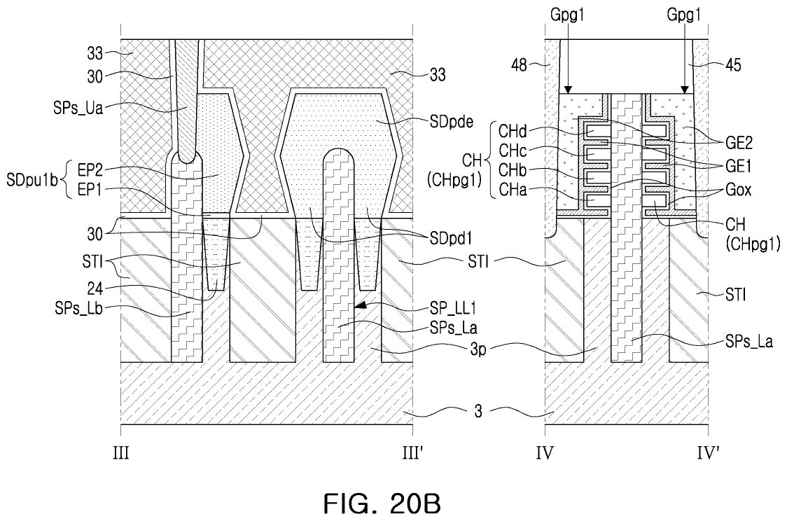

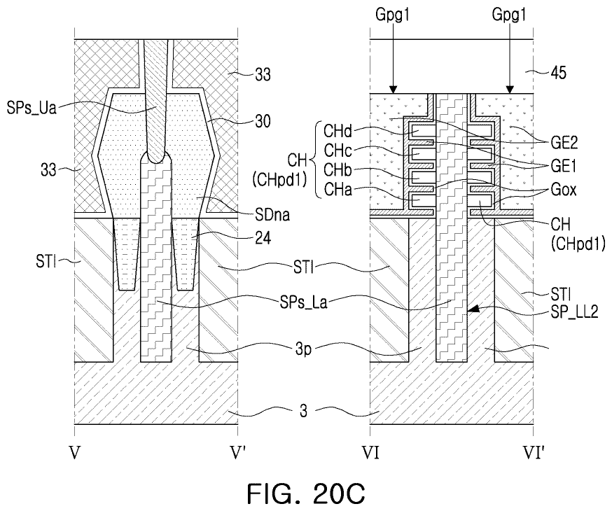

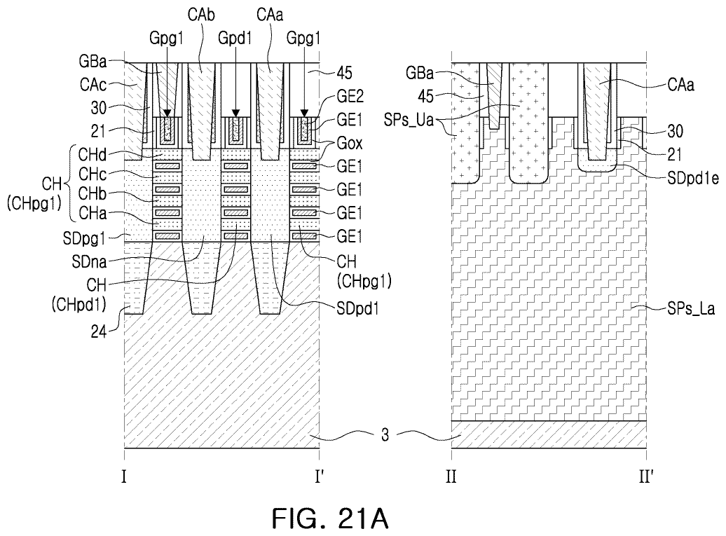

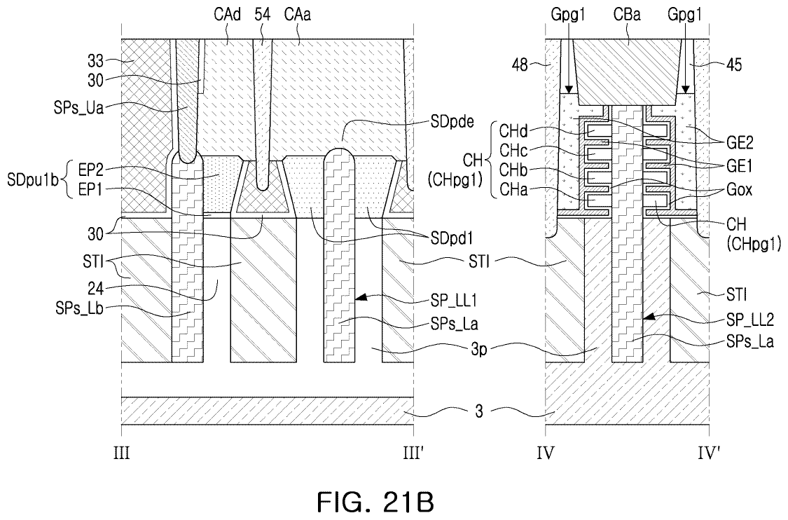

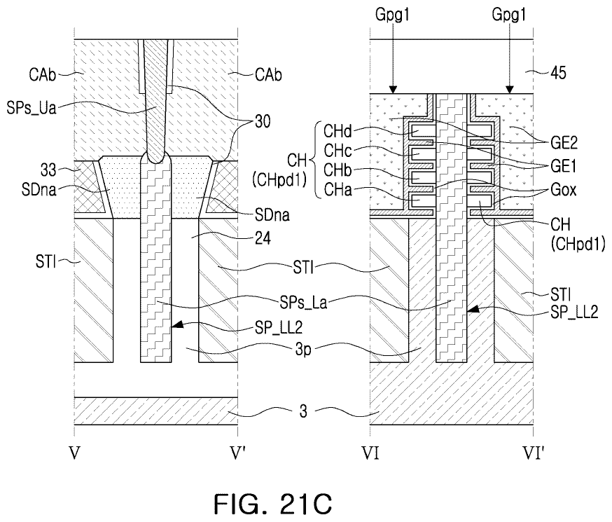

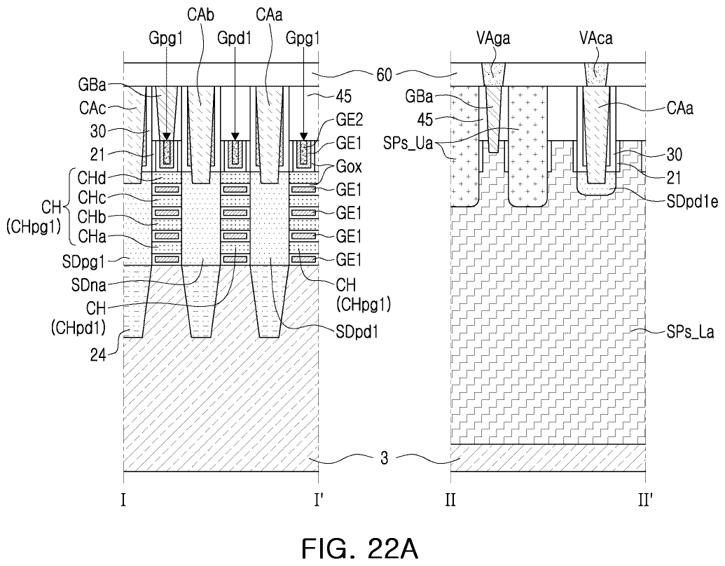

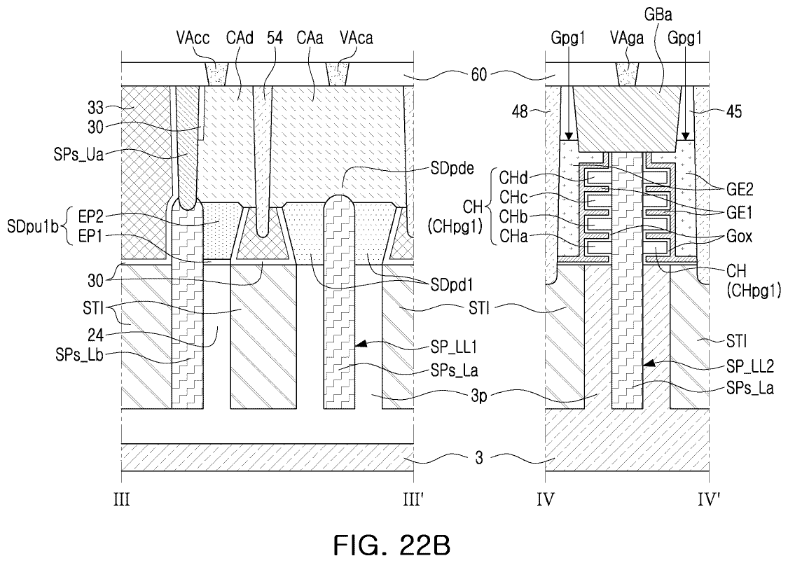

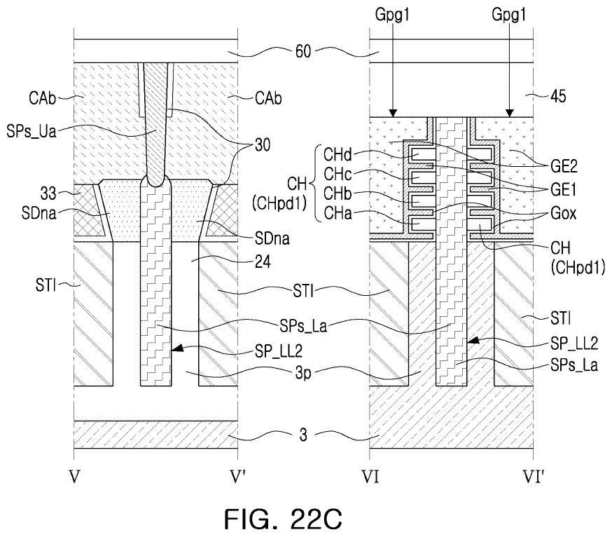

In the description below, an example of a method of manufacturing a semiconductor device according to an example embodiment will be described with reference to FIGS. 12A to 23C. Final plane shapes and cross-sectional shapes of the elements described in FIGS. 12A to 23C may be the same as those of one of the example embodiments described in FIGS. 1 to 11 above. Thus, the plane shapes and cross-sectional shapes of the elements described below may be described based on the example embodiments described in FIGS. 1 to 11 above. In FIGS. 12A to 23C, FIGS. 12A, 13A, 14A, 15A, 16A, 17A, 18A, 19A, 20A, 21A, 22A, and 23A are cross-sectional diagrams illustrating regions taken along lines I-I′ and II-II′ in FIG. 1. FIGS. 12B, 13B, 14B, 15B, 16B, 17B, 18B, 19B, 20B, 21B, FIGS. 22B, and 23B are cross-sectional diagrams illustrating regions taken along lines III-III′ and IV-IV′ in FIG. 1. FIGS. 12C, 13C, 14C, 15C, 16C, 17C, 18C, 19C, 20C, 21C, 22C, and 23C are cross-sectional diagrams illustrating regions taken along lines V-V′ and VI-VI′ in FIG. 1.

Referring to FIGS. 1, 4A, 12A, 12B, and 12C, sacrificial layers 6 and semiconductor layers 9 alternately and repeatedly stacked on a semiconductor substrate 3 may be formed. The sacrificial layers 6 may include a first sacrificial layer 6a, a second sacrificial layer 6b, a third sacrificial layer 6c, a fourth sacrificial layer 6d, and a fifth sacrificial layer 6e stacked sequentially. The semiconductor layers 9 may include a first semiconductor layer 9a between the first sacrificial layer 6a and the second sacrificial layer 6b, a second semiconductor layer 9b between the second sacrificial layer 6b and the third sacrificial layer 6c, a third semiconductor layer 9c between the third sacrificial layer 6c and the fourth sacrificial layer 6d, and a fourth semiconductor layer 9d between the fourth sacrificial layer 6d and the fifth sacrificial layer 6e.

The sacrificial layers 6 and semiconductor layers 9 may be formed through an epitaxial growth process. A material of the sacrificial layers 6 may be different from a material of the semiconductor layers 9. For example, the sacrificial layers 6 may be formed of a SiGe material, and the semiconductor layers 9 may be formed of a Si material.

Lower separation patterns SPs_L penetrating the sacrificial layers 6 and the semiconductor layers 9 and extending into the semiconductor substrate 3 may be formed. The lower separation patterns SPs_L may be formed of an insulating material such as silicon nitride. Each of the lower separation patterns SPs_L may have a line shape extending in the first horizontal direction X.

In the semiconductor substrate 3, a region disposed on the same level as the lower separation patterns SPs_L may be defined as a substrate protrusion 3p.

Trenches may be formed by patterning the sacrificial layers 6 and the semiconductor layers 9, and insulating patterns STI partially filling the trenches may be formed. The insulating patterns STI may be formed on a level lower than a level of the sacrificial layers 6 and the semiconductor layers 9. The remaining sacrificial layers 6 and semiconductor layers 9 may be in contact with the lower separation patterns SPs_L.

Referring to FIGS. 1, 4A, 13A, 13B, and 13C, sacrificial gate lines 15 and 18 may be formed on the sacrificial layers 6, the semiconductor layers 9, the lower separation patterns SPs_L, and the insulating separation patterns STI. Each of the sacrificial gate lines 15 and 18 may be a line shape extending in the second horizontal direction Y. Each of the sacrificial gate lines 15 and 18 may include a sacrificial gate layer 15 and a sacrificial capping layer 18 on the sacrificial gate layer 15.

While forming the sacrificial gate lines 15 and 18, the fifth sacrificial layer 6e may be etched, and a portion of the lower separation patterns SPs_L may be etched.

Referring to FIGS. 1, 4A, 14A, 14B, and 14C, an insulating spacer 21 covering a side surface of the etched fifth sacrificial layer 6e extending downwardly and covering side surfaces of the sacrificial gate lines 15 and 18, and side surfaces of the etched lower separation patterns SPs_L.

The sacrificial layers 6 and the semiconductor layers 9 may be etched by performing an etching process using the sacrificial gate lines 15, 18 and the insulating spacer 21 as an etch mask. The etched semiconductor layers 9 may be defined as channel regions CH. While etching the sacrificial layers 6 and the semiconductor layers 9, a portion of the lower separation patterns SPs_L may be etched.

Referring to FIGS. 1, 4A, 4B, 15A, 15B, and 15C, upper separation patterns SPs_U may be formed. The forming the upper separation patterns SPs_U may include forming a sacrificial material layer, patterning the sacrificial material layer to form openings exposing the lower separation patterns SPs_L, forming the upper separation patterns SPs_U from the openings, and removing the sacrificial material layer. In each of the upper separation patterns SPs_U, side surfaces opposing each other in the second horizontal direction Y may have a negative slope. For example, in the second horizontal direction Y, each of the upper separation patterns SPs_U may have a width decreasing downwardly.

Referring to FIGS. 1, 4A, 4B, 16A, 16B, and 16C, openings may be formed by etching the substrate protrusions 3p of the semiconductor substrate 3 disposed on both sides of the sacrificial gate lines 15 and 18, and epitaxial layers 24 may be formed in the openings. The epitaxial layers 24 may be a SiGe epitaxial layer or a Ge epitaxial layer.

Referring to FIGS. 1, 4A, 4B, 17A, 17B, and 17C, a NMOS source/drain process and a PMOS source/drain process may be performed. The order of performing the NMOS source/drain process and the PMOS source/drain process may be varied.

Source/drain patterns SDpd1, SDpd2, SDna, SDnb, SDpg1, SDpg2, and SDpde having N-type conductivity may be formed using the NMOS source/drain process. The source/drain patterns SDpd1, SDpd2, SDna, SDnb, SDpg1, SDpg2, and SDpde having N-type conductivity may be formed as an epitaxial layer different from the epitaxial layer 24, for example, may be formed as a Si epitaxial layer.

Source/drain patterns SDpu1a, SDpu1b, SDpu2a, and SDpu2b having P-type conductivity may be formed using the PMOS source/drain process. Each of the source/drain patterns SDpu1a, SDpu1b, SDpu2a, and SDpu2b having P-type conductivity may include a first epitaxial layer EP1 different from the epitaxial layers 24 and a second epitaxial layer EP2 different from the first epitaxial layer EP1 on the first epitaxial layer EP1. The first epitaxial layer EP1 may be formed of a Si epitaxial layer or a SiGe layer having a Ge composition different from the SiGe epitaxial layer of the epitaxial layers 24.

Referring to FIGS. 1, 4A, 4B, 18A, 18B, and 18C, an insulating liner 30 and an interlayer insulating layer 33 on the insulating liner 30 may be formed sequentially, a level of an upper surface of the interlayer insulating layer 33 may be formed to be lower than that of an upper surface of the sacrificial gate layer 15 by partially etching the interlayer insulating layer 33, a sacrificial material layer 36 may be formed on the interlayer insulating layer 33 partially etched, and the sacrificial material layer 36 and the insulating liner 30 may be planarized until the sacrificial capping layer 18 and the upper separation patterns SPs_U are exposed.

Referring to FIGS. 1, 4A, 4B, 19A, 19B, and 19C, gate trenches 39 may be formed by removing the sacrificial gate lines 15 and 18. Gate openings 42 may be formed by removing the sacrificial layers 6 exposed by the gate trenches 39.

Referring to FIGS. 1, 4A, 4B, 20A, 20B, and 20C, gates GATE may be formed by performing a gate process.

Forming the gates GATE may include forming gate dielectric layers Gox, forming first gate electrodes GE1 on the gate dielectric layers Gox, and forming second gate electrodes GE2 on the first gate electrodes GE1. The gates GATE may be spaced apart from each other by the lower separation patterns SPs_L.

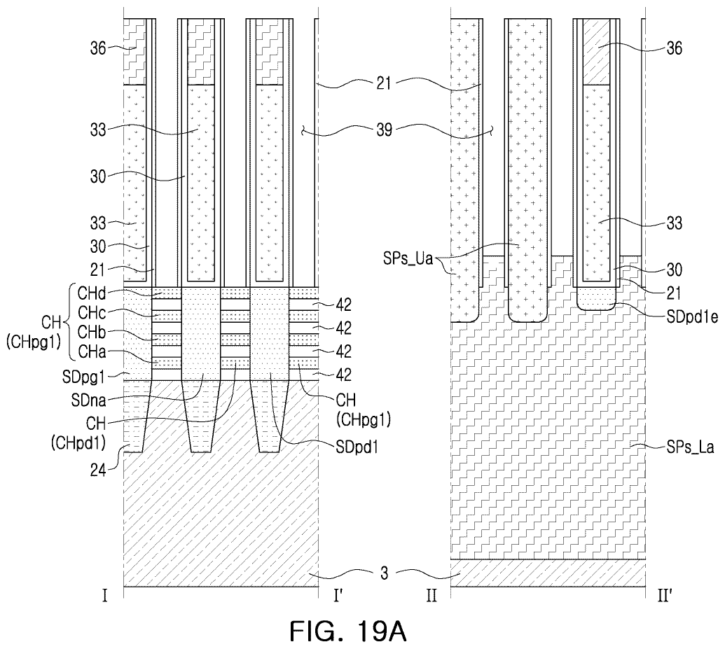

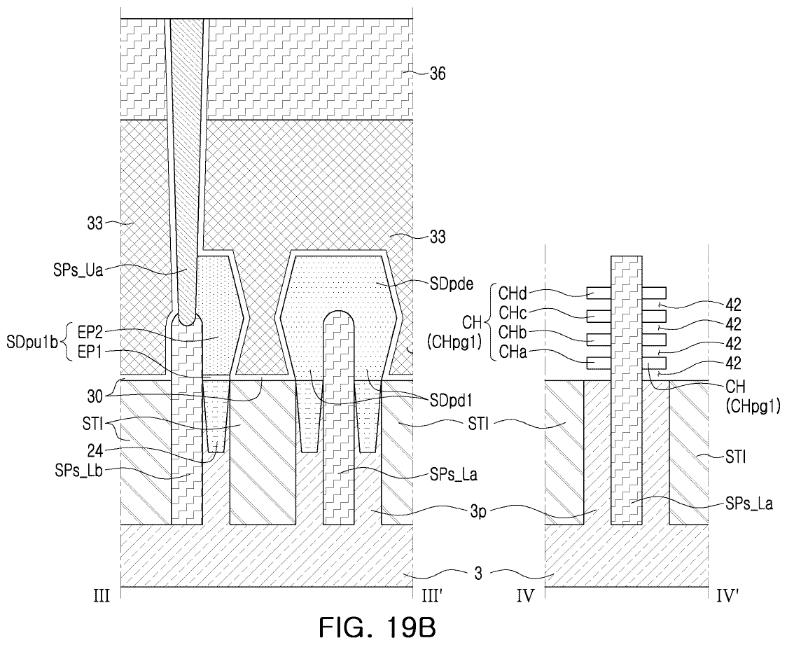

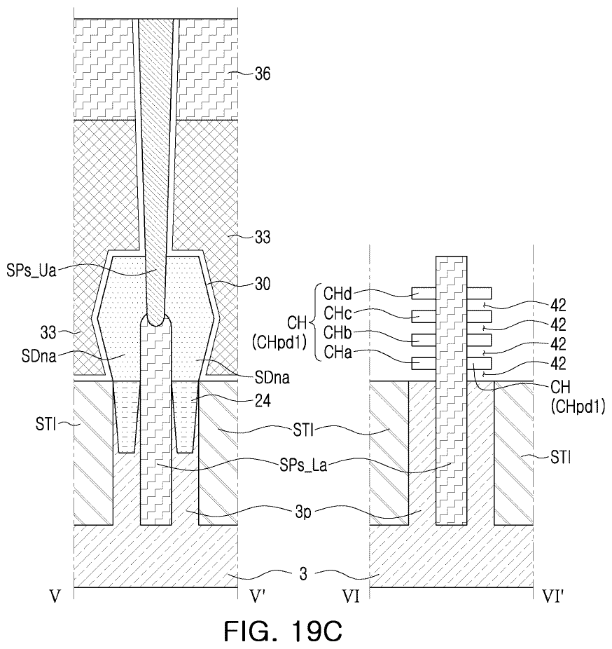

The gate dielectric layers Gox and the first gate electrodes GE1 may fill the gate openings (42 in FIGS. 19A to 19C), and the second gate electrodes GE2 may partially fill the gate trenches (39 in FIGS. 19A to 19C).

Gate capping patterns 45 filling the other portion of the gate trenches (39 in FIGS. 19A to 19C) may be formed on the gates GATE, and by performing a planarization process, the capping material layers 36 may be removed and a level of the interlayer insulating layer 33 and the upper separation patterns SPs_U may be reduced.

Gate separation patterns 48 passing between gates GATE which need to be separated from each other among the gates GATE disposed on the insulating patterns STI, penetrating the gate capping patterns 45 and the insulating liner 30, and extending into the insulating patterns STI may be formed.

Referring to FIGS. 1, 4A, 4B, 4C, 4D, 21A, 21B, and 21C, source/drain contact plugs CA may be formed. before forming the source/drain contact plugs CA or after forming the source/drain contact plugs CA, gate connection plugs GB may be formed.

In an example, openings exposing the source/drain patterns SD may be formed by etching the interlayer insulating layer 33, a portion of the source/drain patterns SD exposed by the preliminary openings may be etched, and source/drain contact plugs CA filling the openings and in contact with the source/drain patterns SD may be formed.

In an example, gate openings exposing at least the gates GATE may be formed by etching the interlayer insulating layer 33 and the gate capping patterns 45, and gate connection plugs GB filling the gate openings may be formed. Here, among the gate connection plugs GB, to form the third gate connection plug GBc as illustrated in FIGS. 4B, 4C and 4D, the gate opening may expose the seventh source/drain contact plug CAg, the second gate electrode GE2 of the first PMOS gate Gpu1, the first gate dummy gate Gd1, and the second lower separation pattern SPs_Ub.

Among the source/drain contact plugs CA disposed on the insulating patterns STI, a contact separation pattern 54 passing between the source/drain contact plugs CA requiring separation and extending into the interlayer insulating layer 33 may be formed. For example, the contact separation pattern 54 passing between the first source/drain contact plug CAa and the fourth source/drain contact plug Cad, extending into the interlayer insulating layer 33, and electrically separating the first source/drain contact plug CAa from the fourth source/drain contact plug CAd may be formed.

Referring to FIGS. 1, 4A to 4D, 22A, 22B, and 22C, a first intermetallic insulating layer 60 may be formed on the contact separation pattern 54, the gate separation pattern 48, the source/drain contact plugs CA, and the gate connection plugs GB.

Conductive vias VA penetrating the first intermetallic insulating layer 60 and electrically connected to the source/drain contact plugs CA and the gate connection plugs GB may be formed.

Referring to FIGS. 1, 4A to 4E, 23A, 23B, and 23C, wiring patterns M1 electrically connected to the conductive vias VA in the first intermetallic insulating layer 60 and the conductive vias VA may be formed. The wiring patterns M1 may include the ground voltage line VSS, the voltage power line VDD, the wordline WL, the first bitline BL1, and the second bitline BL2 described in FIG. 4D.

A second intermetallic insulating layer 63 may be formed on the first intermetallic insulating layer 60 and the conductive vias VA. The second intermetallic insulating layer 63 may fill at least a space between side surfaces of the wiring patterns M1.

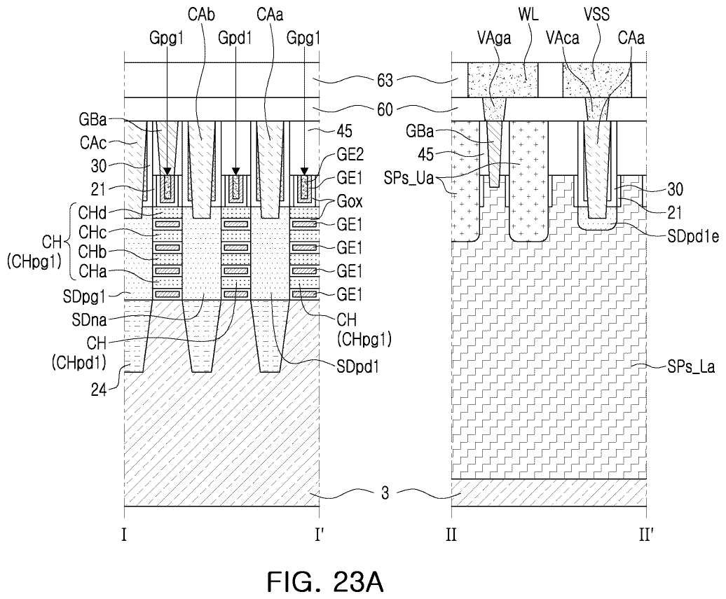

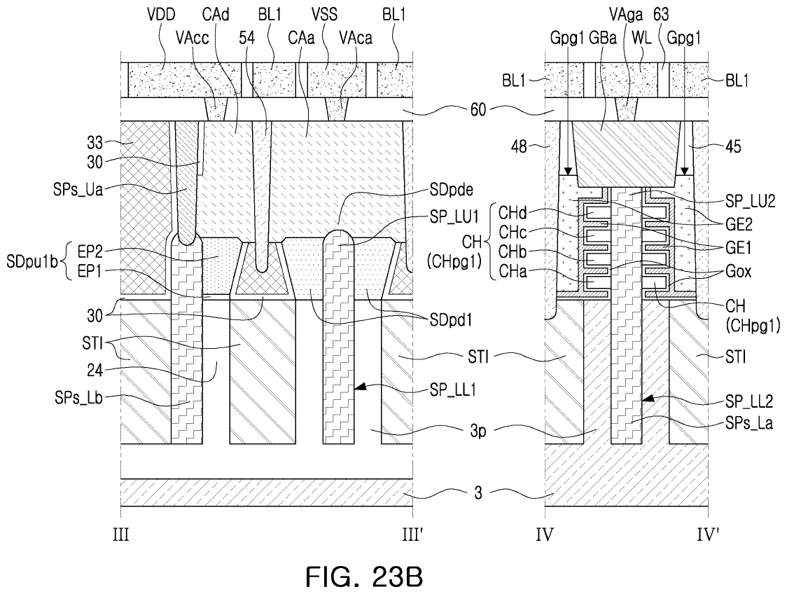

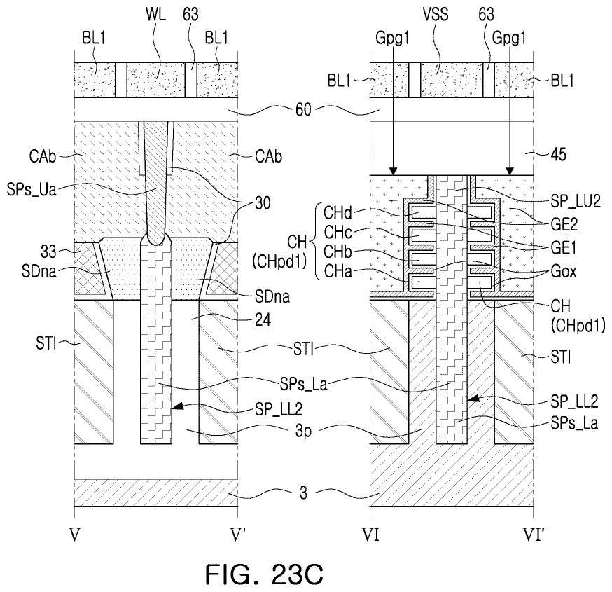

Referring back to FIGS. 1 to 7, 3 of the semiconductor substrate (FIGS. 23A to 23C) and the substrate protrusions (3P in FIGS. 23A to 23C) may be removed. After removing the substrate protrusions 3p, the epitaxial layers (24 in FIGS. 23a to 23c) may be removed. Thereafter, a base 70 and protrusions 70p extending from the base 70 and in contact with lower surfaces of the above source/drain patterns SD may be formed.

In the second circuit region C2, a peripheral contact hole exposing the lower surface of the first peripheral source/drain pattern SD_La may be formed. A lower peripheral contact plug 85 in contact with lower surfaces of the first peripheral source/drain pattern SD_La may be formed in the peripheral contact hole.

A backside wiring pattern 95 electrically connected to the lower peripheral contact plug 85 may be formed below the base 70.

A backside insulating layer 90 covering at least a side surface of the backside wiring pattern 95 below the base 70 may be formed. In example embodiments, the backside wiring pattern 95a may be formed after the backside insulating layer 90 is formed.

According to the aforementioned example embodiments, source/drain patterns disposed on both sides of the lower separation pattern may be provided. Also, channel regions and gates disposed on both sides of the lower separation pattern may be provided. Also, an upper separation pattern disposed on the lower separation pattern may be provided. The lower and upper separation patterns, the source/drain patterns, the channel regions, and the gates may increase integration density of a semiconductor device.

While example embodiments have been illustrated and described above, it will be apparent to those skilled in the art that modifications and variations may be made without departing from the scope of inventive concepts as defined by the appended claims.

What is claimed is:

1. A semiconductor device, comprising:
a first lower separation pattern including a first portion, the first portion including a first lower separation region and a first upper separation region on the first lower separation region;
a first source/drain pattern and a second source/drain pattern on both sides of the first upper separation region, respectively;
a common source/drain contact plug on the first source/drain pattern, the second source/drain pattern, and the first upper separation region, the common source/drain contact plug being electrically connected to the first source/drain pattern and the second source/drain pattern;
a first conductive via electrically connected to the common source/drain contact plug and on the common source/drain contact plug; and
a first wiring pattern electrically connected to the first conductive via and on the first conductive via.

2. The semiconductor device of claim 1, further comprising:
a source/drain extension pattern extending from the first source/drain pattern and the second source/drain pattern, wherein
the source/drain extension pattern extends between the common source/drain contact plug and an upper surface of the first upper separation region.

3. The semiconductor device of claim 1,
wherein the first lower separation pattern further includes a second portion extending from the first portion, and
wherein the second portion of the first lower separation pattern includes a second lower separation region and a second upper separation region on the second lower separation region.

4. The semiconductor device of claim 3, further comprising:
a plurality of first channel layers on a first side of the second upper separation region of the first lower separation pattern, the plurality of first channel layers being stacked and spaced apart from each other in a vertical direction;
a plurality of second channel layers on a second side of the second upper separation region of the first lower separation pattern, the plurality of second channel layer being stacked and spaced apart from each other in the vertical direction;
a first gate on the first side of the second upper separation region of the first lower separation pattern; and
a second gate on a second side of the second upper separation region of the first lower separation pattern,
wherein the second gate is spaced apart from the first gate by the second upper separation region, and
wherein the plurality of second channel layers are spaced apart from the plurality of first channel layers by the second upper separation region.

5. The semiconductor device of claim 4,
wherein a lower surface of the second lower separation region is at a same level as a lower surface of the first lower separation region, and
wherein an upper surface of the second upper separation region is at a higher level than an upper surface of the first upper separation region.

6. The semiconductor device of claim 4, further comprising:
a common gate connection plug in contact with an upper surface of a gate electrode of the first gate, an upper surface of the second upper separation region, and an upper surface of a gate electrode of the second gate.

7. The semiconductor device of claim 6, further comprising:
a second conductive via on the common gate connection plug; and
a second wiring pattern on the second conductive via,
wherein the second wiring pattern is at a same level as the first wiring pattern.

8. The semiconductor device of claim 1, further comprising:
an insulating base; and
insulating patterns on the insulating base,
wherein the first lower separation region is between the insulating patterns.

9. The semiconductor device of claim 1, further comprising:
a second lower separation pattern disposed at a same level as the first lower separation pattern, the second lower separation pattern having a second lower separation region and a second upper separation region on the second lower separation region;
an upper separation pattern in contact with the second lower separation pattern and on the second lower separation pattern; and
a third source/drain pattern and a fourth source/drain pattern on both sides of the second upper separation region and spaced apart from each other.

10. The semiconductor device of claim 9, further comprising:
a lower source/drain contact plug below the third source/drain pattern and in contact with the third source/drain pattern; and
an upper source/drain contact plug on the fourth source/drain pattern and in contact with the fourth source/drain pattern.

11. A semiconductor device, comprising:
a lower separation pattern including overlap regions and a non-overlap region between the overlap regions, a first side surface of the lower separation pattern opposing a second side surface of the lower separation pattern;
upper separation patterns on the overlap regions of the lower separation pattern, the upper separation patterns being spaced apart from each other;
a first channel region, a first gate, and a first source/drain pattern on the first side surface of the lower separation pattern;
a second channel region, a second gate, and a second source/drain pattern on the second side surface of the lower separation pattern;
a source/drain contact plug on the first source/drain pattern, the second source/drain pattern, and the non-overlap region of the lower separation pattern, the source/drain contact plug being electrically connected to the first source/drain pattern and second source/drain pattern;
a first conductive via on the source/drain contact plug; and
a first wiring pattern on the first conductive via, wherein
a portion of the source/drain contact plug vertically overlapping the non-overlap region is between the upper separation patterns.

12. The semiconductor device of claim 11, further comprising:
a source/drain extension pattern extending from the first source/drain pattern and the second source/drain pattern, wherein
the source/drain extension pattern extends to between the source/drain contact plug and an upper surface of the non-overlap region of the lower separation pattern.

13. The semiconductor device of claim 11, wherein the source/drain contact plug is in contact with the non-overlap region of the lower separation pattern.

14. The semiconductor device of claim 11, wherein the first conductive via vertically overlaps the non-overlap region of the lower separation pattern.

15. The semiconductor device of claim 11,
wherein the first channel region includes first channel layers stacked and spaced apart from each other in a vertical direction, and
wherein the second channel region includes second channel layers stacked and spaced apart from each other in the vertical direction.

16. The semiconductor device of claim 11, further comprising:
insulating patterns,
wherein the lower separation pattern includes
a first lower separation region and a first upper separation region on the first lower separation region, and
a second lower separation region and a second upper separation region on the second lower separation region,
wherein the first upper separation region is between the first source/drain pattern and the second source/drain pattern,
wherein the second upper separation region is between the first gate and the second gate, and
wherein the first lower separation region and the second lower separation region are between the insulating patterns.

17. A semiconductor device, comprising:
a first lower separation pattern and a second lower separation pattern, the second lower separation pattern being parallel to the first lower separation pattern;
a first access source/drain pattern, a first access channel region, a first common source/drain pattern, a first NMOS channel region, and a first NMOS source/drain pattern on a side surface of the first lower separation pattern facing the second lower separation pattern, and arranged sequentially in a first horizontal direction;
a first PMOS source/drain pattern, a first PMOS channel region, and a second PMOS source/drain pattern on a first side surface of the second lower separation pattern facing the first lower separation pattern, and arranged sequentially in the first horizontal direction;
a fourth PMOS source/drain pattern, a second PMOS channel region, and a third PMOS source/drain pattern disposed on a second side surface of the second lower separation pattern opposing a first side surface of the second lower separation pattern, and arranged sequentially in the first horizontal direction;
a first access gate vertically overlapping the first access channel region;
a first NMOS gate vertically overlapping the first NMOS channel region;
a first PMOS gate vertically overlapping the first PMOS channel region and connected to the first NMOS gate;
a second PMOS gate vertically overlapping the second PMOS channel region;
a first source/drain contact plug on the first NMOS source/drain pattern;
a second source/drain contact plug electrically connected to the first common source/drain pattern and the first PMOS source/drain pattern;
a third source/drain contact plug on the first access source/drain pattern;
a fourth source/drain contact plug on the second PMOS source/drain pattern;
a first gate connection plug connected to the first access gate; and
a second gate connection plug including a first extension portion and a second extension portion,
wherein the first extension portion extends in the first horizontal direction and is connected to the second source/drain contact plug,
wherein a second horizontal direction is perpendicular to the first horizontal direction,
wherein the second extension portion extends from the first extension portion in the second horizontal direction, vertically overlaps the second lower separation pattern, and is connected to the second PMOS gate,
wherein the first common source/drain pattern, the first PMOS source/drain pattern, and the third PMOS source/drain pattern are arranged sequentially in the second horizontal direction, and
wherein the second extension portion of the second gate connection plug is in contact with a gate electrode of the second PMOS gate.

18. The semiconductor device of claim 17, further comprising:
upper separation patterns on the second lower separation pattern,
wherein a portion of the second extension portion vertically overlapping the second lower separation pattern is between the upper separation patterns.

19. The semiconductor device of claim 17, wherein each of the first access channel region, the first NMOS channel region, the first PMOS channel region, and the second PMOS channel region includes channel layers spaced apart from each other and vertically stacked.

20. The semiconductor device of claim 17, further comprising:
a conductive via on the fourth source/drain contact plug; and
a wiring pattern on the conductive via, the wiring pattern electrically connected to the conductive via and extending in the first horizontal direction,
wherein the wiring pattern vertically overlaps the second lower separation pattern and the second gate connection plug.
